(19) United States
(12) Patent Application Publication
(10) Pub. No.: US 2013/0313690 A1
(43) Pub. Date: Nov. 28, 2013

(54) SEMICONDUCTOR DEVICE

(71) Applicant: Elpida Memory, Inc., Tokyo (JP)

(72) Inventor: Toru MIYAZAKI, Tokyo (JP)

(73) Assignee: Elpida Memory, Inc., Tokyo (JP)

(21) Appl. No.: 13/898,030

(22) Filed: May 20, 2013

(30) Foreign Application Priority Data
May 28, 2012 (JP) 2012-120655

(51) Int. Cl. H01L 23/48

(52) U.S. Cl. CPC H01L 23/481
USPC 257/621

(57) ABSTRACT

Disclosed herein is a device that includes a semiconductor substrate, a plurality of first electrodes formed over the semiconductor substrate and arranged in line in a first direction, a plurality of second electrodes formed over the semiconductor substrate and arranged in line in the first direction on a left side of an associated one of the first electrodes, and a plurality of third electrodes formed over the semiconductor substrate and arranged in line in the first direction on a right side of an associated one of the first electrodes. Each of the first electrodes is configured to be supplied with a corresponding electrical potential, whereas each of the second and third electrodes is in an electrical floating state serving as a dummy electrode.

This application is based upon and claims the benefit of priority from Japanese patent application No. 2012-120655, filed on May 28, 2012, the disclosure of which is incorporated herein in its entirety by reference.

### TECHNICAL FIELD

The present invention relates to a semiconductor device.

### BACKGROUND

Some of semiconductor devices having a plurality of semiconductor chips (semiconductor devices) being stacked so as to enhance the functionality have a structure in which upper and lower semiconductor chips are electrically connected to each other by through electrodes (through silicon vias (TSVs)) and bump electrodes. Those through electrodes are formed so as to extend through the semiconductor chips.

For example, JP-A 2010-287859 (Patent Literature 1) discloses a method of stacking a semiconductor chip having through electrodes formed therein on another chip. FIG. 7 of Patent Literature 1 discloses a structure in which bump electrodes for conduction with another chip (bump electrodes 3 and 6 in FIG. 2) are arranged near the center of the chip.

Furthermore, JP-A 2010-272737 (Patent Literature 2) discloses a method of forming through electrodes. In Patent Literature 2, a seed layer (the metal seed film 7 in FIG. 2) is brought into contact with a wiring layer (the second wiring layer 5 in FIG. 2) formed on a front face of a substrate. A bump electrode of copper (the first projecting electrode 9 in FIG. 2) is formed on the seed layer by an electroplating method. At that time, a photoresist film (the resist film 8 in FIG. 2) is patterned on the seed layer, so that the bump electrode is formed in an opening portion of the photoresist film (an exposed portion of the seed layer).

According to the study of the inventor, when patterns are developed in a photoresist in order to form bump electrodes arrayed near the center of the chip (semiconductor device) as in Patent Literature 1 by an electroplating method as in Patent Literature 2, then deformation may be caused to patterns located at a peripheral portion of the array by disturbance of the periodicity of the patterns. This is because the outermost bump electrode at a dense portion in which multiple lines of patterns are arranged serves as a boundary with a thin portion. Therefore, the outermost bump electrode is likely to be affected by the film stress of the thin portion, and pattern deformation is likely to be caused at the outermost bump electrode.

Particularly, in a case where an oxygen (O₂) plasma treatment is performed to make a surface of the photoresist hydrophilic after formation of the patterns in the photoresist, the deformation is accelerated by additional influence from the temperature and the like. Therefore, irregularities are likely to be caused in shape of the outermost bump electrode.

When a Sn—Ag film is formed for solder on a bump electrode made of copper, an O₂ plasma treatment is performed before the plating. Deformation is further caused so as to generate a gap between a sidewall of the bump electrode and the photoresist. A plating liquid enters the gap upon the Sn—Ag plating, so that a thin Sn—Ag film is formed on the sidewall of the bump electrode. Then the Sn—Ag film is not dissolved in a removal liquid when the seed layer is removed after removal of the photoresist. Therefore, copper (the bump electrode) on which the Sn—Ag film is present is not etched and is left. Irregularly etched portions are likely to be generated at a portion of copper that is not covered with the Sn—Ag film by influence from change of the flow of the liquid.

If the opening diameter is varied as described above, then the height of bump electrodes to be formed would be varied. This may be a cause of a faulty connection of through electrodes upon stacking the chips. Furthermore, if the Sn—Ag film is left, the solder state varies due to the presence of the Sn—Ag film on the sidewall of the bump electrodes upon stacking the chips. Accordingly, stacking anomaly is likely to be caused.

### SUMMARY

In one embodiment, there is provided a device that includes a semiconductor substrate, a plurality of first electrodes formed over the semiconductor substrate and arranged in line in a first direction, a plurality of second electrodes formed over the semiconductor substrate and arranged in line in the first direction on a left side of an associated one of the first electrodes, and a plurality of third electrodes formed over the semiconductor substrate and arranged in line in the first direction on a right side of an associated one of the first electrodes, in which each of the first electrodes is configured to be supplied with a corresponding electrical potential, and each of the second and third electrodes is in an electrical floating state serving as a dummy electrode.

In another embodiment, such a device is provided that comprises: a semiconductor substrate including a first main surface and a second main surface opposite to the first main surface; a plurality of first through-substrate vias each penetrating the semiconductor substrate, the first through-substrate vias being arranged to form a matrix including a plurality of rows and columns; a plurality of first electrodes formed over the first main surface of the semiconductor substrate, each the first electrodes being vertically aligned with an associated one of the first through-substrate vias and electrically connected to a selected one of the first through-substrate vias; a first set of dummy electrodes each being in an electrical floating state; and a second set of dummy electrodes each being in an electrical floating state; each of the first and second sets of dummy electrodes being formed over one of the first and second main surfaces of the semiconductor substrate to sandwich the first electrodes therebetween.

In still another embodiment, there is provided a device that comprises: a semiconductor substrate including first, second and third areas, the second area being between the first and third areas; a plurality of first through-substrate vias each formed in the second area and each penetrating the semiconductor substrate, the first through-substrate vias being arranged in line in a first direction; a plurality of first electrodes each formed over the second area of the semiconductor substrate, the first electrodes being arranged in line in the first direction so that each of the first electrodes being vertically aligned with an associated one of the first through-substrate vias; a plurality of second electrodes each formed over the first area of the semiconductor substrate and in an electrical floating state, the second electrodes being arranged in line in the first direction; and a plurality of third electrodes each formed over the third area of the semiconductor substrate and in an electrical floating state, the third electrodes being arranged in line in the first direction so that each of the third electrodes cooperates with an associated one of the second electrodes to sandwich an associated one of the first electrodes therebetween in a second direction that is substantially perpendicular to the first direction.

### BRIEF DESCRIPTION OF THE DRAWINGS

The above features and advantages of the present invention will be more apparent from the following description of certain preferred embodiments taken in conjunction with the accompanying drawings, in which

FIG. 1A is a cross-sectional view explanatory of a configuration of a semiconductor device according to a first exemplary embodiment of the present invention and corresponds to a cross-section taken along line A1-A1 of FIG. 1B.

FIG. 1B is a diagram showing a front side of the semiconductor device for explaining the configuration of the semiconductor device according to the first exemplary embodiment of the present invention.

FIG. 2 is a diagram showing a multilayered structure in which semiconductor devices as illustrated in FIGS. 1A and 1B are stacked.

FIG. 3 is a diagram explanatory of a method of manufacturing a semiconductor device according to the first exemplary embodiment of the present invention.

FIG. 4A is a cross-sectional view explanatory of a method of manufacturing a semiconductor device according to the first exemplary embodiment of the present invention and corresponds to a cross-section taken along line A1-A1 of FIG. 4B.

FIG. 4B is a diagram showing the front side of a semiconductor device for explaining a method of manufacturing a semiconductor device according to the first exemplary embodiment of the present invention.

FIG. 5A is a cross-sectional view explanatory of a method of manufacturing a semiconductor device according to the first exemplary embodiment of the present invention and corresponds to a cross-section taken along line A1-A1 of FIG. 5B.

FIG. 5B is a diagram showing the front side of a semiconductor device for explaining a method of manufacturing a semiconductor device according to the first exemplary embodiment of the present invention.

FIG. 6A is a cross-sectional view explanatory of a method of manufacturing a semiconductor device according to the first exemplary embodiment of the present invention and corresponds to a cross-section taken along line A1-A1 of FIG. 6B.

FIG. 6B is a diagram showing the front side of a semiconductor device for explaining a method of manufacturing a semiconductor device according to the first exemplary embodiment of the present invention.

FIG. 7 is a cross-sectional view explanatory of a method of manufacturing a semiconductor device according to the first exemplary embodiment of the present invention.

FIG. 8A is a cross-sectional view explanatory of a method of manufacturing a semiconductor device according to the first exemplary embodiment of the present invention and corresponds to a cross-section taken along line A1-A1 of FIG. 8B.

FIG. 8B is a diagram showing the front side of the semiconductor device for explaining a method of manufacturing a semiconductor device according to the first exemplary embodiment of the present invention.

FIG. 9A is a cross-sectional view explanatory of a method of manufacturing a semiconductor device according to the first exemplary embodiment of the present invention and corresponds to a cross-section taken along line A1-A1 of FIG. 9B.

FIG. 9B is a diagram showing the front side of a semiconductor device for explaining a method of manufacturing a semiconductor device according to the first exemplary embodiment of the present invention.

FIG. 10 is a cross-sectional view explanatory of a method of manufacturing a semiconductor device according to the first exemplary embodiment of the present invention.

FIG. 11A is a cross-sectional view explanatory of a configuration of a semiconductor device according to a second exemplary embodiment of the present invention and corresponds to a cross-section taken along line A2-A2 of FIG. 11B.

FIG. 11B is a diagram showing a front side of the semiconductor device for explaining the configuration of the semiconductor device according to the second exemplary embodiment of the present invention.

FIG. 12 is a diagram showing a multilayered structure in which semiconductor devices according to the second exemplary embodiment of the present invention as illustrated in FIGS. 11A and 11B are stacked.

FIG. 13 is a cross-sectional view explanatory of a method of manufacturing a semiconductor device according to the second exemplary embodiment of the present invention.

FIG. 14A is a cross-sectional view explanatory of a method of manufacturing a semiconductor device according to the second exemplary embodiment of the present invention and corresponds to a cross-section taken along line A2-A2 of FIG. 14B.

FIG. 14B is a diagram showing the front side of the semiconductor device for explaining a method of manufacturing a semiconductor device according to the second exemplary embodiment of the present invention.

FIG. 15A is a cross-sectional view explanatory of a method of manufacturing a semiconductor device according to the second exemplary embodiment of the present invention and corresponds to a cross-section taken along line A2-A2 of FIG. 15B.

FIG. 15B is a diagram showing the front side of the semiconductor device for explaining a method of manufacturing a semiconductor device according to the second exemplary embodiment of the present invention.

FIG. 16A is a cross-sectional view explanatory of a method of manufacturing a semiconductor device according to the second exemplary embodiment of the present invention and corresponds to a cross-section taken along line A2-A2 of FIG. 16B.

FIG. 16B is a diagram showing the front side of the semiconductor device for explaining a method of manufacturing a semiconductor device according to the second exemplary embodiment of the present invention.

FIG. 17A is a cross-sectional view explanatory of a method of manufacturing a semiconductor device according to the second exemplary embodiment of the present invention and corresponds to a cross-section taken along line A2-A2 of FIG. 17B.

FIG. 17B is a diagram showing the front side of the semiconductor device for explaining a method of manufacturing a semiconductor device according to the second exemplary embodiment of the present invention.

FIG. 18A is a cross-sectional view explanatory of a configuration of a semiconductor device according to a third exemplary embodiment of the present invention and corresponds to a cross-section taken along line A3-A3 of FIG. 18B.

FIG. 18B is a diagram showing a rear side of the semiconductor device for explaining the configuration of the semiconductor device according to the third exemplary embodiment of the present invention.

FIG. 19 is a diagram showing a multilayered structure in which semiconductor devices according to the third exemplary embodiment of the present invention as illustrated in FIGS. 18A and 18B are stacked.

FIG. 20A is a cross-sectional view explanatory of a method of manufacturing a semiconductor device according to the third exemplary embodiment of the present invention and corresponds to a cross-section taken along line A3-A3 of FIG. 20B.

FIG. 20B is a diagram showing the rear side of the semiconductor device for explaining a method of manufacturing a semiconductor device according to the third exemplary embodiment of the present invention.

FIG. 21A is a cross-sectional view explanatory of a method of manufacturing a semiconductor device according to the third exemplary embodiment of the present invention and corresponds to a cross-section taken along line A3-A3 of FIG. 21B.

FIG. 21B is a diagram showing the rear side of the semiconductor device for explaining a method of manufacturing a semiconductor device according to the third exemplary embodiment of the present invention.

FIG. 22A is a cross-sectional view explanatory of a configuration of a semiconductor device according to a fourth exemplary embodiment of the present invention and corresponds to a cross-section taken along line A4-A4 of FIGS. 22B and 22C.

FIG. 22B is a diagram showing a front side of the semiconductor device for explaining the configuration of the semiconductor device according to the fourth exemplary embodiment of the present invention.

FIG. 22C is a diagram showing a rear side of the semiconductor device for explaining the configuration of the semiconductor device according to the fourth exemplary embodiment of the present invention.

FIG. 23 is a diagram showing a multilayered structure in which semiconductor devices according to the fourth exemplary embodiment of the present invention as illustrated in FIGS. 22A to 22C are stacked.

FIG. 24A is a cross-sectional view explanatory of a method of manufacturing a semiconductor device according to the fourth exemplary embodiment of the present invention and corresponds to a cross-section taken along line A4-A4 of FIG. 24B.

FIG. 24B is a diagram showing the rear side of the semiconductor device for explaining a method of manufacturing a semiconductor device according to the fourth exemplary embodiment of the present invention.

FIG. 25A is a cross-sectional view explanatory of a method of manufacturing a semiconductor device according to the fourth exemplary embodiment of the present invention and corresponds to a cross-section taken along line A4-A4 of FIG. 25B.

FIG. 25B is a diagram showing the rear side of the semiconductor device for explaining a method of manufacturing a semiconductor device according to the fourth exemplary embodiment of the present invention.

FIG. 26A is a diagram showing a variation of the shape of dummy patterns.

FIG. 26B is a diagram showing a variation of the shape of dummy patterns.

FIG. 26C is a diagram showing a variation of the shape of dummy patterns.

### DESCRIPTION OF EXEMPLARY EMBODIMENTS

Some examples of a method of manufacturing a semiconductor device according to the present invention and a semiconductor device produced by such a method will be described in detail below with reference to the accompanying drawings. For the purpose of illustration, the accompanying drawings used in the following description may enlarge some characteristic portions. The dimension and ratio of components are not necessarily the same as those of an actual product. Furthermore, materials and dimension mentioned in the following description are provided by way of example. Therefore, the present invention is not limited to those examples. Thus, the present invention can be implemented with any possible changes not departing from the spirit of the present invention.

### First Exemplary Embodiment

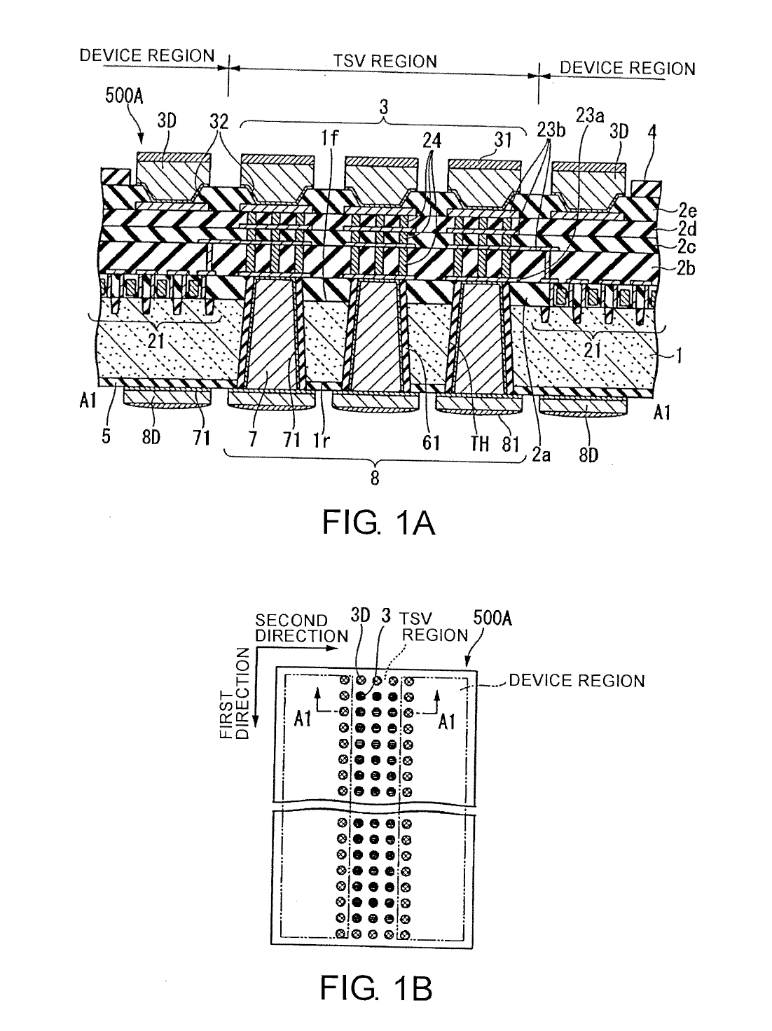

FIG. 1A is a cross-sectional view explanatory of a configuration of a semiconductor device according to a first exemplary embodiment of the present invention. FIG. 1B is a diagram showing a front side of the semiconductor device for explaining the configuration of the semiconductor device according to the first exemplary embodiment of the present invention. FIG. 1A is a cross-sectional view taken along line A1-A1 of FIG. 1B.

First, as shown in FIG. 1B, the semiconductor device 500A includes a through silicon via or through-substrate via (TSV) region extending longitudinally at a central portion of the semiconductor device 500A and device regions disposed on both sides of the TSV region. Although not shown in FIG. 1A, a plurality of TSVs (Through-Substrate Vias or Through-Silicon Vias) are formed in the TSV region. Each of the TSVs 3 is supplied with a corresponding electrical potential to serve as a signal TSV or a power supply TSV, which will discussed in detail later. The TSV region may be referred to as a bump electrode region. For the convenience of description the longitudinal direction of the TSV region is referred to as a first direction, and a direction perpendicular to the longitudinal direction is referred to as a second direction.

Referring to the cross-sectional view of FIG. 1A, the semiconductor device 500A has a multi-level wiring structure in which first to fifth interlayer dielectrics 2a-2e are formed on a semiconductor substrate 1 and multi-level wiring layers 23a and 23b are formed at different levels between the first to fifth interlayer dielectrics 2a-2e. The wiring layers 23a and the upper-layer wires 23b are electrically connected to each other by via plugs 24. Some of the wiring layers 23a are formed so as to have a circular shape in at least the TSV region illustrated in FIG. 1B. Those wiring layers 23a correspond to TSV through holes TH, which will be described later.

Circuit elements 21, such as gate electrode/gate insulator films and source/drain (S/D) regions, are formed in the device regions on a front face if of the semiconductor substrate 1, i.e., a surface of the semiconductor substrate 1 on which circuits are formed.

A passivation film (polyimide) 4 of a resin layer is formed on the fifth interlayer dielectric 2e in the device regions. A plurality of front bump electrodes 3 (first electrode group) are formed on the fifth interlayer dielectric 2e in the TSV region. For example, the front bump electrodes 3 are made of copper. The front bump electrodes 3 are connected to the upper-layer wires 23b in the fifth interlayer dielectric 2e while seed layers 32 are interposed between the front bump electrodes 3 and the upper-layer wires 23b. A protective film 31 is formed on upper surfaces of the front bump electrodes 3 in order to prevent the front bump electrodes 3 from being oxidized. For example, the protective film 31 is made of gold. The electrodes 3 include such an electrode that serves to receive and/or output an electrical signal. Another electrode may be included in the electrodes 3, that receives a power supply voltage.

As can readily be seen from FIG. 1B, dummy front bump electrodes 3D (second electrodes) are formed so as to surround the front bump electrodes 3 located within the TSV region. As shown in FIG. 1A, no TSVs 7 are formed at positions corresponding to the dummy front bump electrodes 3D. Therefore, there are no via plugs corresponding to the dummy front bump electrodes 3D. In other words, each of the dummy bump electrodes is in an electrical floating state. As described later, however, the dummy front bump electrodes 3D are produced in the same manufacturing process as that for the front bump electrodes 3. Therefore, an upper-layer wire 23b formed in the fifth interlayer dielectric 2e, a seed layer 32, and a protective film 31 are present for each of the dummy front bump electrodes 3D.

Meanwhile, the semiconductor substrate 1 has a thickness of about 40 μm, for example. A rear protective film 5, such as silicon nitride, for example, is formed on a rear face 1r of the semiconductor substrate 1. Each of the TSV through holes TH formed by dry etching has a sidewall covered with an insulation film. Thus, TSV sidewall insulation rings 61 are formed on the sidewalls of the TSV through holes TH. The rest of the space in each of the TSV through holes TH is filled with a dielectric such as copper while a seed layer 71 is interposed between the dielectric and the TSV sidewall insulation ring 61. Thus, the TSVs 7 are formed. Furthermore, rear bump electrodes (e.g., copper) 8 are formed so that exposed portions of the TSVs 7 are covered with the rear bump electrodes 8 while a seed layer 71 is interposed between exposed portions of the TSVs 7 and the rear bump electrodes 8. Solder (Sn—Ag alloy) 81 is formed on surfaces of the rear bump electrodes 8 by plating.

Dummy rear bump electrodes 8D, which correspond to the dummy front bump electrodes 3D formed on the front face 1f, are formed so as to surround the rear bump electrodes 8 located within the TSV region. As described later, the dummy rear bump electrodes 8D are produced in the same manufacturing process as that for the rear bump electrodes 8. Therefore, a seed layer 71 and solder 81 are present for each of the dummy rear bump electrodes 8D.

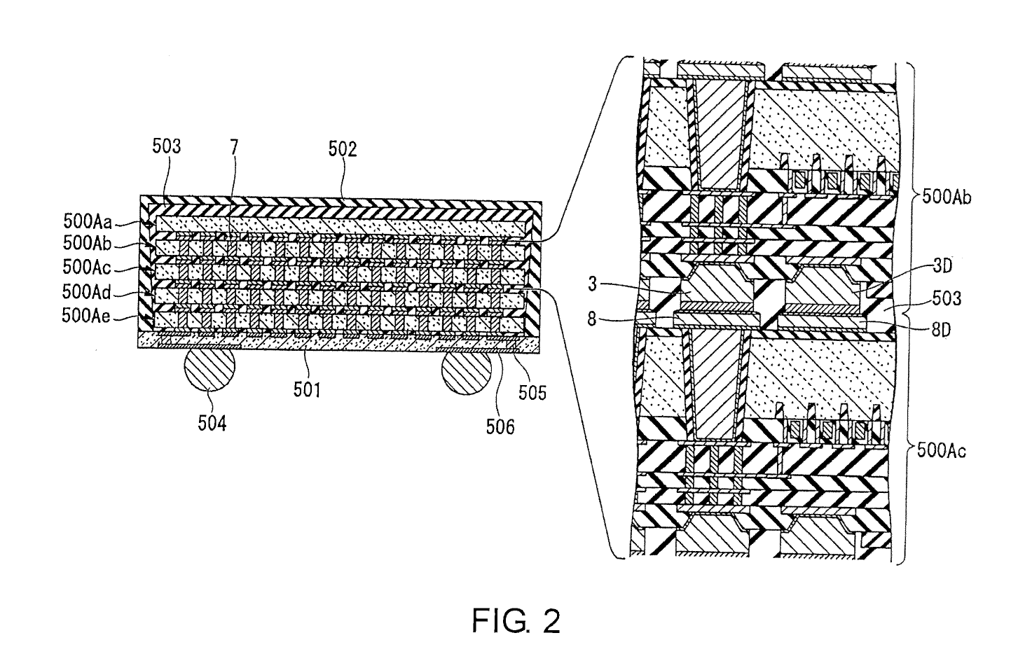

FIG. 2 is a diagram showing a multilayered structure in which a plurality of semiconductor devices as illustrated in FIGS. 1A and 1B are stacked.

Referring to FIG. 2, a plurality of semiconductor devices 500Aa-500Ae are stacked on a first surface of a package substrate 501. The semiconductor devices 500Aa-500Ad serve as core chips, and the semiconductor device 500Ae serves as an interface chip. Each of the semiconductor devices 500Aa-500Ae is electrically connected to an upper semiconductor device and/or a lower semiconductor device via front bump electrodes 3 and rear bump electrodes 8. Thus, a multilayered structure is formed. The dummy front bump electrodes 3D and the dummy rear bump electrodes 8D are also physically connected to each other in the same manner as the front bump electrodes 3 and the rear bump electrodes 8 are connected to each other.

Each of the semiconductor devices 500Aa-500Ae is covered with a mold resin 502, so that internal gaps are filled with an underfill 503. Thus, the semiconductor devices 500Aa-500Ae are sealed in the mold resin 502. A plurality of solder balls 504 are formed on a second surface of the package substrate 501 and electrically connected to the front bump electrodes 3 of the semiconductor device 500Ae via through holes 505 and rewires 506.

The semiconductor device 500Aa is located at the uppermost position of the multilayered structure. Therefore, as long as the semiconductor device 500Aa can bring signals and power supplied from terminals of the semiconductor device 500Ab into the interior of the semiconductor device 500Aa, those signals supplied from the terminals of the semiconductor device 500Ab does not need to be supplied to any other semiconductor device. Accordingly, the uppermost semiconductor device 500Aa may include no TSVs 7. If no TSVs 7 are formed on the semiconductor device 500Aa, no chip thickness reduction for facilitating formation of TSVs 7 is required for the semiconductor device 500Aa. Therefore, the semiconductor device 500Aa may be made thicker than the semiconductor devices 500b-500d. As a result, for example, deformation of a semiconductor device due to thermal stress generated upon stacking semiconductor devices can be suppressed in a manufacturing process of the multilayered structure. Thus, the yield can be improved.

Although FIG. 2 illustrates an example in which four semiconductor devices 500Aa-500Ad are stacked, the present invention is applicable to a multilayered structure in which two or more semiconductor devices are stacked. Thus, the aforementioned configuration can be applied to a multilayered structure in which the number of semiconductor devices being stacked is other than four. In other words, no through electrodes or terminals may be formed in a semiconductor device stacked at the uppermost layer of a multilayered structure. The semiconductor device stacked at the uppermost layer may be made thicker than other semiconductor devices in the multilayered structure.

From the viewpoint that the same type of semiconductor devices should be configured in the same manner, the uppermost semiconductor device may have through electrodes and terminals as in the case of lower semiconductor devices. The present invention is similarly effective when it is applied to such a multilayered structure.

Next, a method of manufacturing the semiconductor device according to the first exemplary embodiment of the present invention as illustrated in FIGS. 1A and 1B will be described below.

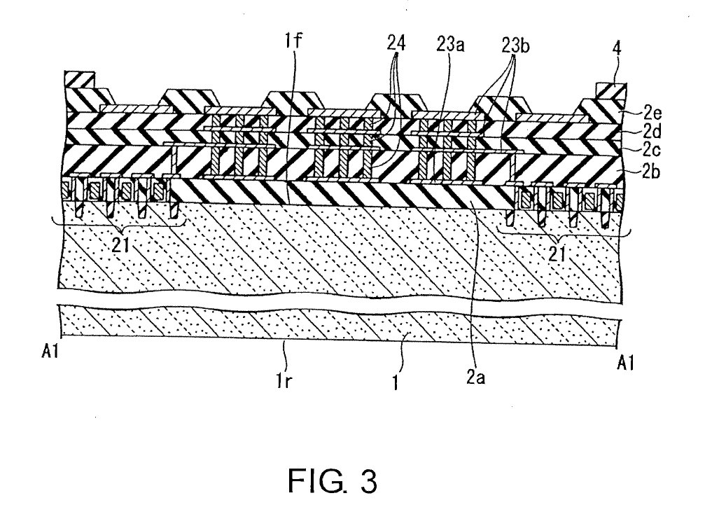

First, in order to produce a structure illustrated in FIG. 3, the following process is performed. Circuit elements 21 such as gate electrode/gate insulation films and source/drain (S/D) regions are formed on a front face if of a semiconductor substrate 1, i.e., a surface of the semiconductor substrate 1 on which circuits are to be formed. At the same time, a first interlayer dielectric 2a is stacked on the front face if of the semiconductor substrate 1. Then a wiring layer 23a of aluminum or the like is formed on the first interlayer dielectric 2a by dry etching with a mask of a photoresist (PR).

Subsequently, second to fifth interlayer dielectrics 2b-2e are stacked on the first interlayer dielectric 2a. An upper-layer wire (e.g., aluminum, copper, or the like) 23b is formed on each of the second to fifth interlayer dielectrics 2b-2e. Those upper-layer wires 23b and the wiring layer 23a are electrically connected to each other by via plugs 24. Then a passivation film (polyimide) 4 of a resin layer is formed on the fifth interlayer dielectric 2e. Furthermore, pad openings are formed in the fifth interlayer dielectric 2e.

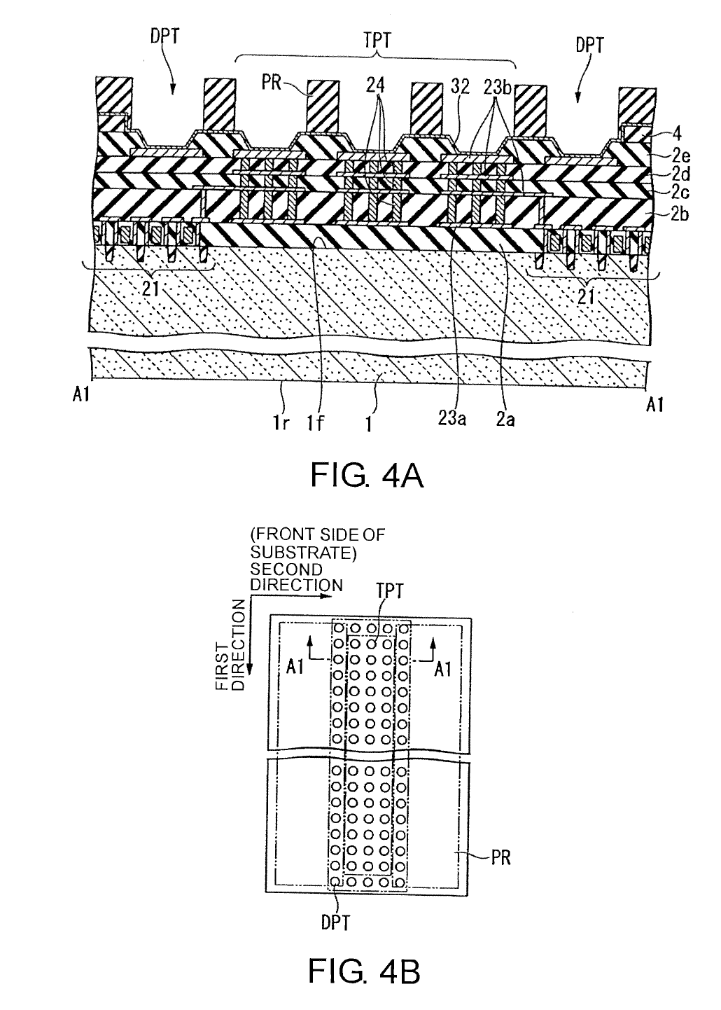

Referring to FIGS. 4A and 4B, a seed layer 32 is then formed on the fifth interlayer dielectric 2e, the upper-layer wire 23b in the openings of the fifth interlayer dielectric 2e, and the passivation film 4 by sputtering. Subsequently, a photoresist film PR is formed on the seed layer 32. Thereafter, main patterns (first patterns) TPT and dummy patterns (second patterns) DPT are formed in the photoresist film PR by a photolithography method.

Specifically, the main patterns TPT are opening patterns formed at positions corresponding to the wiring layers in the TSV region. More specifically, the main patterns TPT are a plurality of dot-like opening patterns arranged two-dimensionally along the first direction and the second direction perpendicular to the first direction on the front side of the semiconductor substrate. Furthermore, the dummy patterns DPT are opening patterns arranged on the extension of the main patterns TPT along the first direction and on the extension of the main patterns TPT along the second direction. In the illustrated example, the dummy patterns DPT are a plurality of dot-like opening patterns arranged two-dimensionally as with the main patterns TPT. In other words, the dummy patterns DPT are dot-like opening patterns surrounding the main patterns TPT in the TSV region as shown in FIG. 4B.

Thus, since the dummy patterns DPT are provided around the main patterns TPT, the main patterns TPT are not located at an edge of the repeated patterns. Therefore, the main patterns TPT are unlikely to be affected by pattern deformation that may be caused at the edge of the repeated patterns.

A distance between the center of the outermost pattern of the main patterns TPT and the center of a dummy pattern DPT is not more than two times a distance between the centers of the closest two patterns of the main patterns TPT. More preferably, as shown in FIGS. 4A and 4B, the distance between the center of the outermost pattern of the main patterns TPT and the center of a dummy pattern DPT is the same as a distance between the centers of the main patterns TPT uniformly arranged. In this case, the periodicity of the overall patterns including the dummy patterns DPT is maintained. No deformation is caused at boundaries between the main patterns TPT and the dummy patterns DPT, or deformation is only caused at the outermost portions of the dummy patterns DPT.

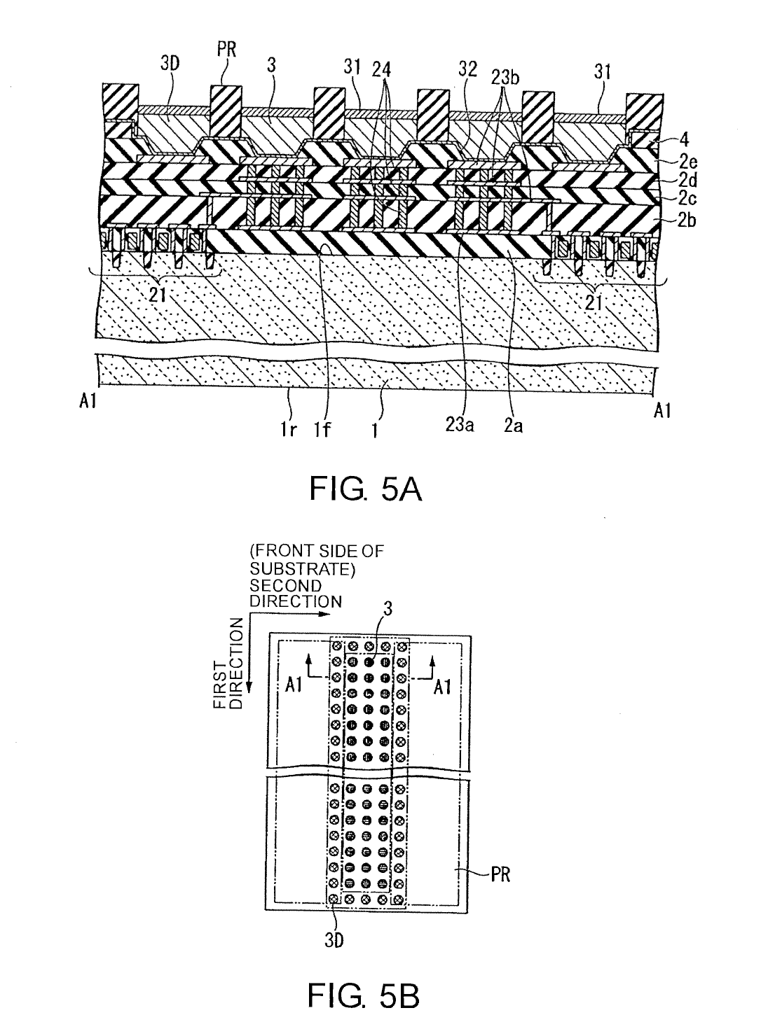

Referring to FIGS. 5A and 5B, an oxygen (O₂) plasma treatment is then performed, for example, in order to improve the wettability of inner walls of the photoresist PR to a plating liquid used in a subsequent step. Front bump electrodes 3 (first electrode group) and dummy front bump electrodes 3D (second electrodes) are formed by a well-known method, such as electroplating, using the seed layer 32. The front bump electrodes 3 are connected to the upper-layer wire 23b formed within the fifth interlayer dielectric 2e. For example, the front bump electrodes 3 and the dummy front bump electrodes 3D are made of copper. A protective film 31, such as a gold film, is formed on upper surfaces of the front bump electrodes 3 and the dummy front bump electrodes 3D in order to prevent the front bump electrodes 3 and the dummy front bump electrodes 3D from being oxidized. Although the front bump electrodes 3 and the dummy front bump electrodes 3D are named differently in this example, they are formed simultaneously in the same manner.

By adjusting the diameter of the dummy patterns DPT and the diameter of the main patterns TPT in the process described in connection with FIGS. 4A and 4B, the height of the bump electrodes 3 and 3D formed within those patterns can be adjusted in the process illustrated in FIGS. 5A and 5B. Particularly, it is preferable to adjust the diameter of the dummy patterns DPT and the diameter of the main patterns TPT so that the height of the dummy front bump electrodes 3D is equal to or lower than the height of the front bump electrodes 3.

In such a case, when the semiconductor devices 500A are stacked as illustrated in FIG. 2, the front bump electrodes 3 are prevented from defectively floating out of contact with the lower-layer electrodes. For example, if electroplating is conducted under conditions that a deposition rate for a region having a smaller pattern diameter is higher than a deposition rate for a region having a larger pattern diameter, then it is preferable to adjust the diameter of the dummy patterns DPT to be equal to or larger than the diameter of the main patterns TPT. On the other hand, if electroplating is conducted under conditions that a deposition rate for a region having a smaller pattern diameter is lower than a deposition rate for a region having a larger pattern diameter, then it is preferable to adjust the diameter of the dummy patterns DPT to be equal to or smaller than the diameter of the main patterns TPT.

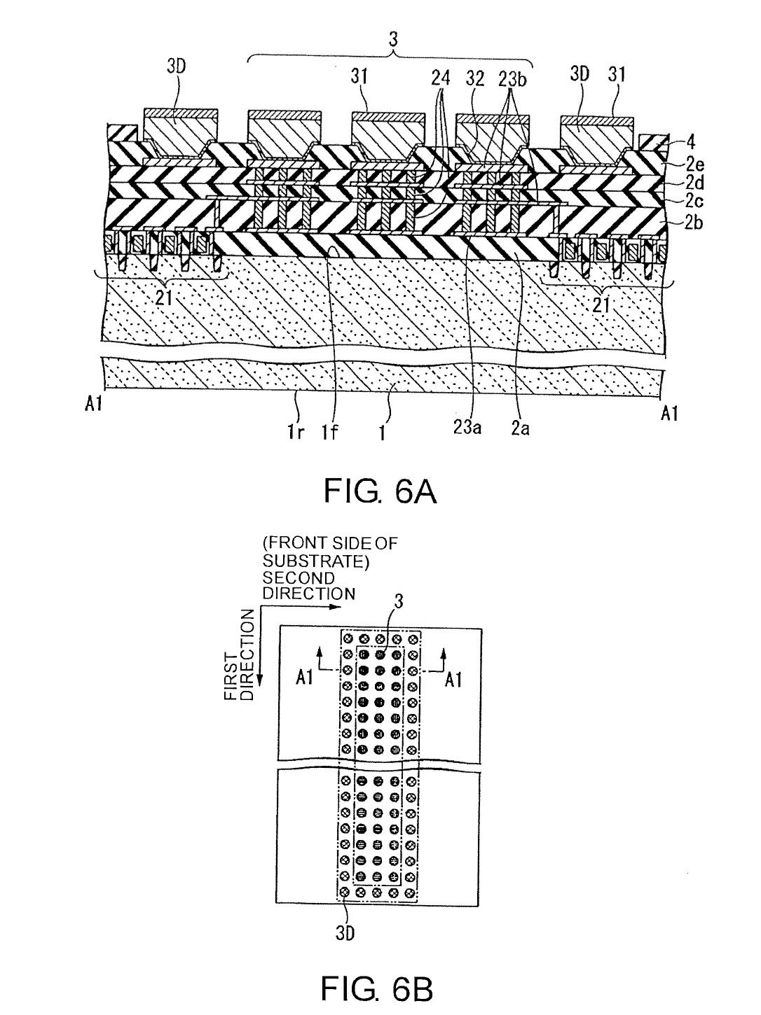

Referring to FIGS. 6A and 6B, the photoresist PR is then removed, and exposed portions of the seed layer 32 are removed by wet etching. At that time, the front bump electrodes 3 and the dummy front bump electrodes 3D are side-etched.

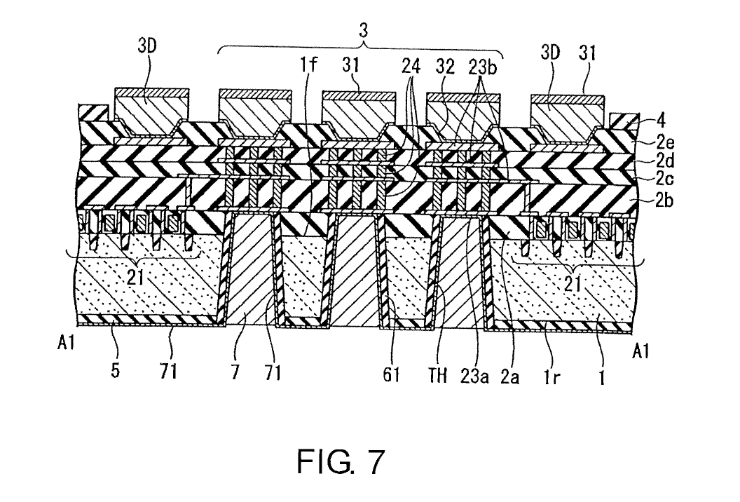

Referring to FIG. 7, the rear face 1r of the semiconductor substrate 1 is then ground (back grind) so that the semiconductor substrate 1 has a thickness of about 40 μm, for example. Subsequently, a rear protective film 5 made of silicon nitride, for example, is formed on the rear face 1r of the semiconductor substrate 1. Furthermore, a photoresist having a pattern for forming TSV through holes TH, which will be described later, is formed on the rear protective film 5. The photoresist is not illustrated in FIG. 7 because it will be removed later. Thereafter, a plurality of TSV through holes TH are formed by dry etching with use of the photoresist as a mask.

Next, the photoresist is removed, and an insulation film is formed on a surface of the remaining rear protective film 5 and over the TSV through holes TH. For example, this insulation film may be a silicon oxide film, a silicon nitride film, or a layered film of a silicon oxide film and a silicon nitride film. At that time, the insulation film is formed so that side surfaces and bottoms of the TSV through holes TH are covered with the insulation film.

Then the insulation film is removed from the surface of the rear protective film 5 and the bottoms of the TSV through holes TH by anisotropic etching (etching-back). Thus, TSV sidewall insulation rings 61 are formed on the side surfaces of the TSV through holes TH.

Subsequently, a thin film of a seed layer 71 is formed, and a TSV conductive film of copper is formed by electroplating. The TSV conductive film is subjected to a chemical mechanical polishing (CMP) process or an etching-back process so as to form TSVs 7. The seed layer 71 is formed of titanium, titanium nitride, tantalum, tantalum nitride, or a multilayered film thereof. The seed layer 71 is not necessarily required.

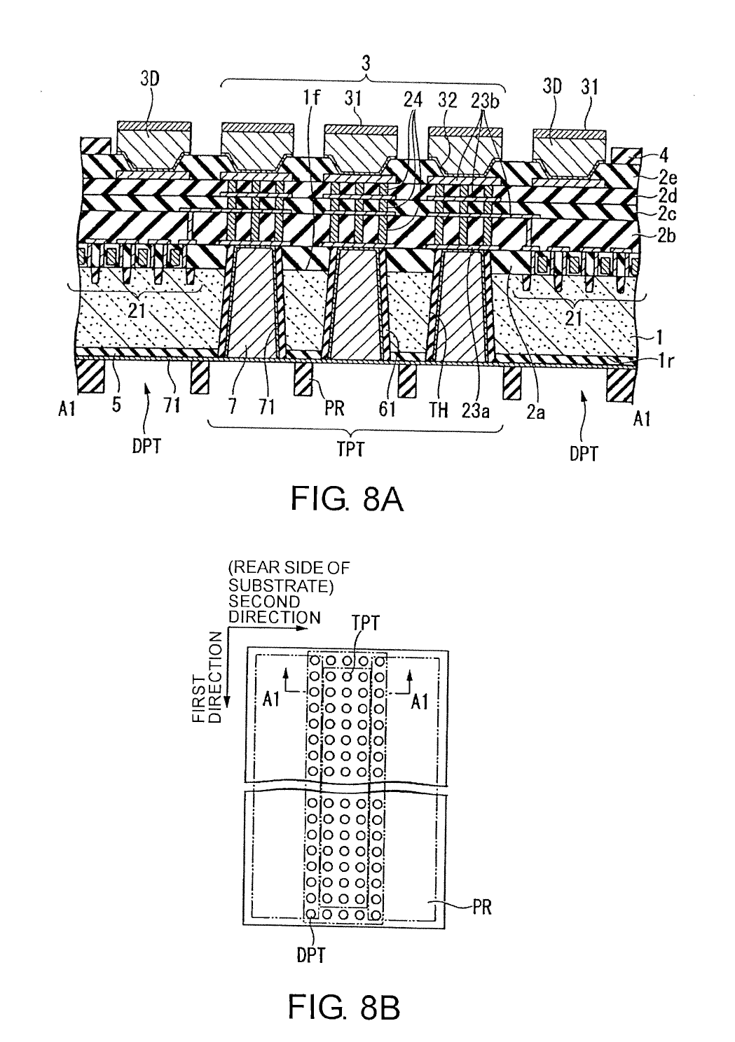

The following description referring to FIGS. 8A to 10 is almost the same as the description on the front side of the semiconductor substrate illustrated in FIGS. 4A to 6B.

Specifically, referring to FIGS. 8A and 8B, a thin film of a seed layer 71 is first formed by sputtering so that exposed portions of the TSVs 7 are covered with the seed layer 71. Then a photoresist film PR is formed on the seed layer 71. Subsequently, main patterns (first pattern group) TPT and dummy patterns (second patterns) DPT are formed by a photolithography method.

Specifically, the main patterns TPT are opening patterns formed at positions corresponding to the TSVs 7. More specifically, the main patterns TPT are a plurality of dot-like opening patterns arranged two-dimensionally along the first direction and the second direction perpendicular to the first direction on the rear side of the semiconductor substrate. Furthermore, the dummy patterns DPT are opening patterns arranged on the extension of the main patterns TPT along the first direction and on the extension of the main patterns TPT along the second direction. In the illustrated example, the dummy patterns DPT are a plurality of dot-like opening patterns arranged two-dimensionally as with the main patterns TPT. In other words, the dummy patterns DPT are dot-like opening patterns surrounding the main patterns TPT in the TSV region as shown in FIG. 8B.

Thus, since the dummy patterns DPT are provided around the main patterns TPT, the main patterns TPT are not located at an edge of the repeated patterns. Therefore, the main patterns TPT are unlikely to be affected by pattern deformation that may be caused at the edge of the repeated patterns.

The discussion on the distances between the centers of the patterns on the front side of the semiconductor substrate can be applied in the same manner to the rear side of the semiconductor substrate. A distance between the center of the outermost pattern of the main patterns TPT and the center of a dummy pattern DPT is not more than two times a distance between the centers of the closest two patterns of the main patterns TPT. More preferably, as shown in FIGS. 8A and 8B, the distance between the center of the outermost pattern of the main patterns TPT and the center of a dummy pattern DPT is the same as a distance between the centers of the main patterns TPT uniformly arranged. In this case, the periodicity of the overall patterns including the dummy patterns DPT is maintained.

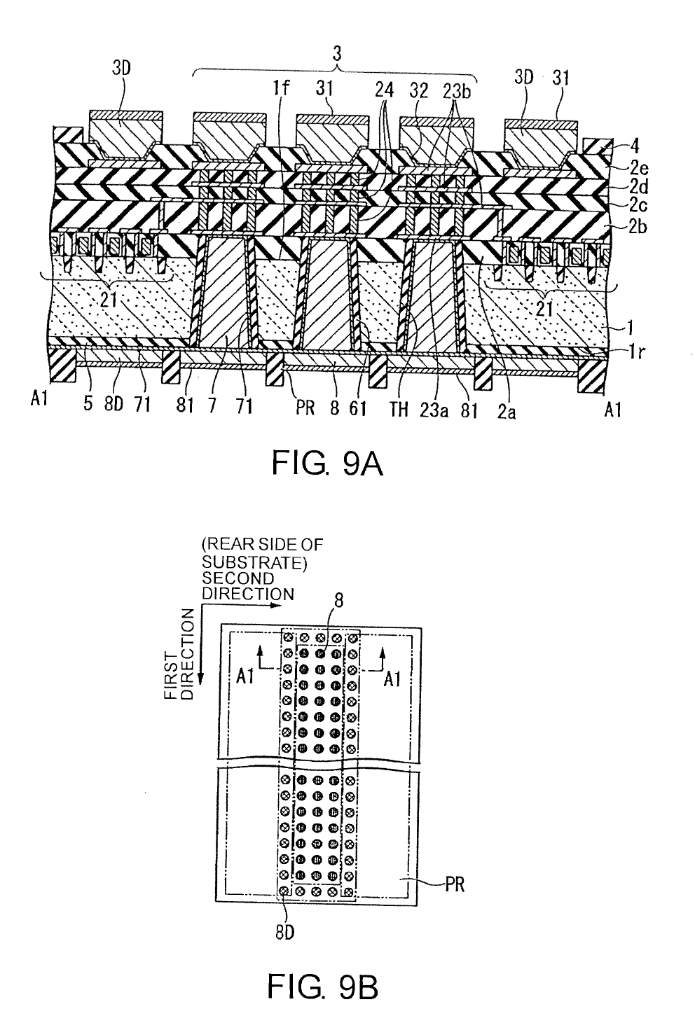

Referring to FIGS. 9A and 9B, rear bump electrodes 8 and dummy rear bump electrodes 8D are formed by a well-known method, such as electroplating, using the seed layer 32. The rear bump electrodes 8 are connected to the TSVs 7. For example, the rear bump electrodes 8 and the dummy rear bump electrodes 8D are made of copper. A protective film 81, such as a gold film, is formed on lower surfaces of the rear bump electrodes 8 and the dummy rear bump electrodes 8D in order to prevent the rear bump electrodes 8 and the dummy rear bump electrodes 8D from being oxidized. Although the rear bump electrodes 8 and the dummy rear bump electrodes 8D are named differently in this example, they are formed simultaneously in the same manner.

By adjusting the diameter of the dummy patterns DPT and the diameter of the main patterns TPT in the process described in connection with FIGS. 8A and 8B, the height of the bump electrodes 8 and 8D formed within those patterns can be adjusted in the process illustrated in FIGS. 9A and 9B. Particularly, it is preferable to adjust the diameter of the dummy patterns DPT and the diameter of the main patterns TPT so that the height of the dummy rear bump electrodes 8D is equal to or lower than the height of the rear bump electrodes 8. In such a case, when the semiconductor devices 500A are stacked as illustrated in FIG. 2, the rear bump electrodes 8 are prevented from defectively floating out of contact with the upper-layer electrodes.

For example, if electroplating is conducted under conditions that a deposition rate for a region having a smaller pattern diameter is higher than a deposition rate for a region having a larger pattern diameter, then it is preferable to adjust the diameter of the dummy patterns DPT to be equal to or larger than the diameter of the main patterns TPT. On the other hand, if electroplating is conducted under conditions that a deposition rate for a region having a smaller pattern diameter is lower than a deposition rate for a region having a larger pattern diameter, then it is preferable to adjust the diameter of the dummy patterns DPT to be equal to or smaller than the diameter of the main patterns TPT.

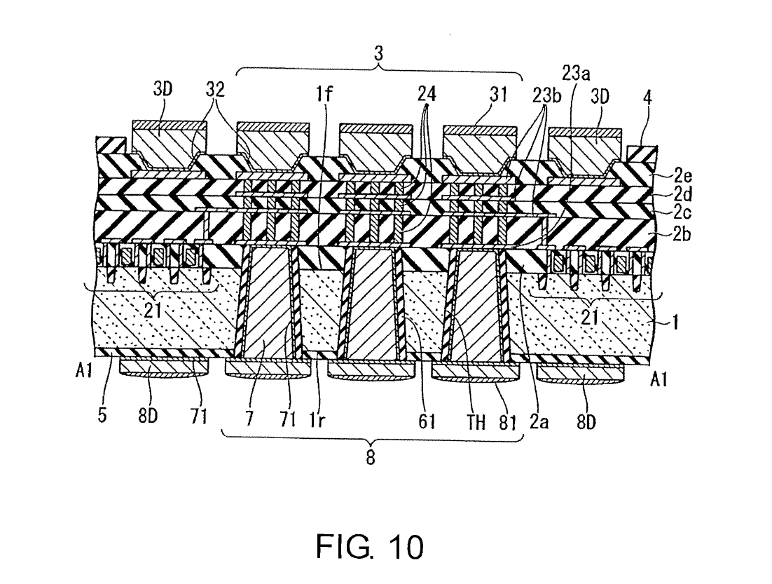

Referring to FIG. 10, the photoresist PR is then removed, and exposed portions of the seed layer 71 are removed by wet etching. At that time, the rear bump electrodes 8 and the dummy rear bump electrodes 8D are side-etched.

Thereafter, a dicing process, a chip mounting process, an assembly process, and the like, which have been well-known, are performed. Thus, a structure illustrated in FIG. 2 is produced.

In the above embodiment, the number of the bump electrodes arranged along the second direction of the device is three. However, the number of the bump electrodes is not limited to this example. Furthermore, the present invention is effective as long as the semiconductor device has a structure having bump electrodes on the front side and the rear side of the substrate in the multilayered structure including the semiconductor devices illustrated in FIG. 2. The present invention is not limited to the structure illustrated in FIG. 2, such as the direction of stacking the semiconductor devices constituting core chips (face-down or face-up) or the presence of TSVs in the uppermost semiconductor device.

According to a method of manufacturing a semiconductor device according to the aforementioned first exemplary embodiment and a semiconductor device manufactured by such a method, when patterns are formed in a photoresist film by a photolithography method to form bump electrodes in a TSV region, the outermost patterns are dummy patterns DPT. Therefore, whatever deformation is caused by irregularity of the periodicity of patterns, such deformation occurs at those dummy patterns DPT. Therefore, no deformation is caused to the main patterns TPT formed in the TSV region. Accordingly, the height of the bump electrodes 3 and 8 does not vary due to the deformation. As a result, no faulty connection is caused upon stacking the semiconductor devices 500A.

### Second Exemplary Embodiment

Next, a method of manufacturing a semiconductor device according to a second exemplary embodiment of the present invention will be described below.

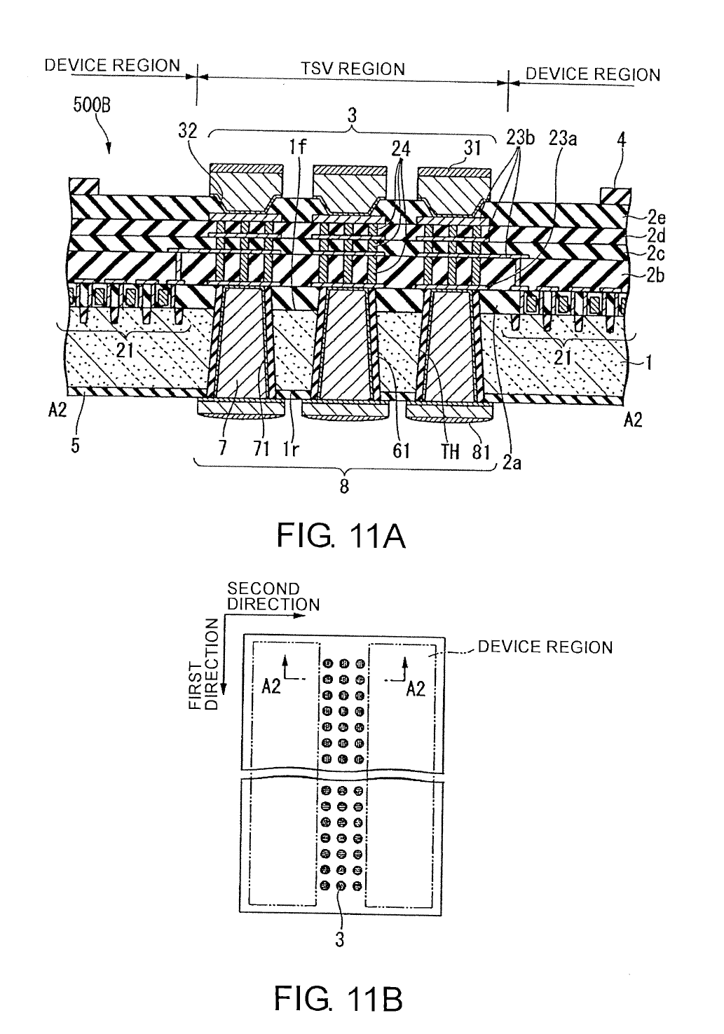

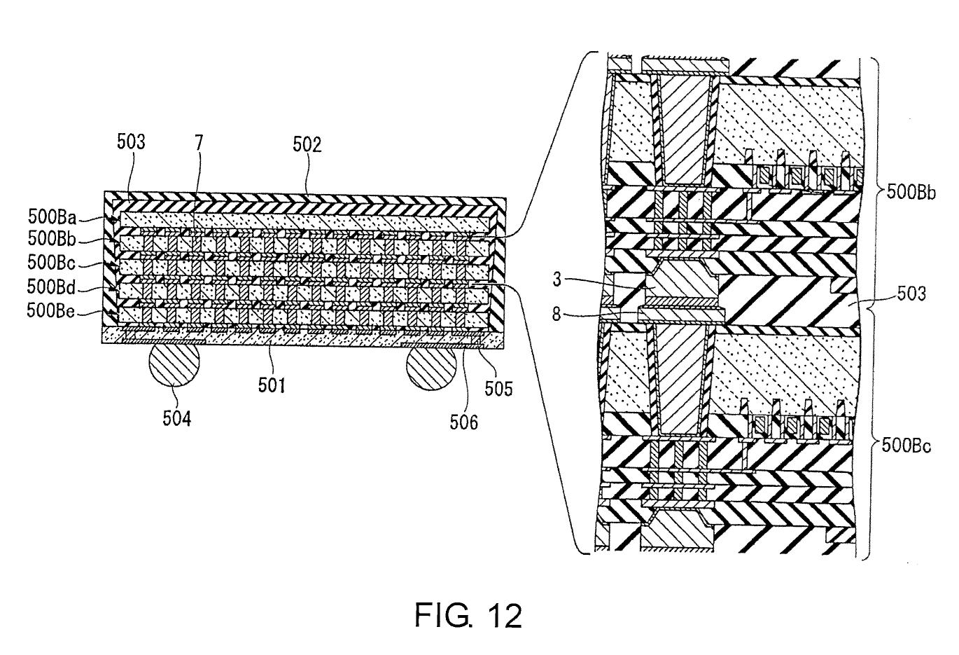

FIG. 11A is a cross-sectional view explanatory of a configuration of a semiconductor device according to a second exemplary embodiment of the present invention. FIG. 11B is a diagram showing a front side of the semiconductor device for explaining the configuration of the semiconductor device according to the second exemplary embodiment of the present invention. FIG. 11A is a cross-sectional view taken along line A2-A2 of FIG. 11B. In other words, FIGS. 11A and 11B correspond to FIGS. 1A and 1B of the first exemplary embodiment. FIG. 12 is a diagram showing a multilayered structure in which a plurality of semiconductor devices according to the second exemplary embodiment of the present invention as illustrated in FIGS. 11A and 11B are stacked. FIG. 12 corresponds to FIG. 2 of the first embodiment. The same components as in the multilayered structure of the semiconductor device according to the first exemplary embodiment shown in FIGS. 1A, 1B, and 2 will be denoted by the same reference numerals, and the explanation thereof is omitted herein.

The semiconductor device according to the second exemplary embodiment differs from the semiconductor device according to the first exemplary embodiment in that no dummy front bump electrodes 3D or dummy rear bump electrodes 8D are provided on the semiconductor device as a product as shown in FIGS. 11A, 11B, and 12. Therefore, a product according to the second exemplary embodiment has no characteristic portions. Instead, the following method of manufacturing a semiconductor device has characteristic portions.

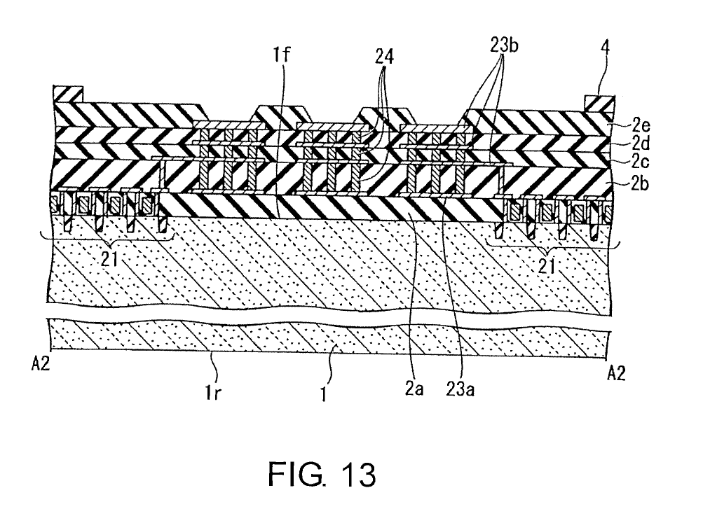

FIGS. 13 to 17B are diagrams explanatory of a method of manufacturing a semiconductor device according to the second exemplary embodiment of the present invention as illustrated in FIGS. 11A and 11B. FIGS. 13 to 17B correspond to FIGS. 3 to 5B, 8A, 8B, 9A, and 9B of the first exemplary embodiment. Description of steps corresponding to FIGS. 6A, 6B, 7, and 10 of the first exemplary embodiment is omitted herein. Furthermore, with regard to FIGS. 13 to 17B, only differences between the steps illustrated in FIGS. 3 to 5B, 8A, 8B, 9A, and 9B and the steps illustrated in FIGS. 13 to 17B are described for the sake of brevity.

A method of manufacturing a semiconductor device according to the second exemplary embodiment differs from that according to the first exemplary embodiment in the following points.

In a step illustrated in FIG. 13, which corresponds to FIG. 3, no upper-layer wires 23b or pad openings are formed at regions (device regions) other than the TSV region in the fifth interlayer dielectric 2e, unlike the first embodiment.

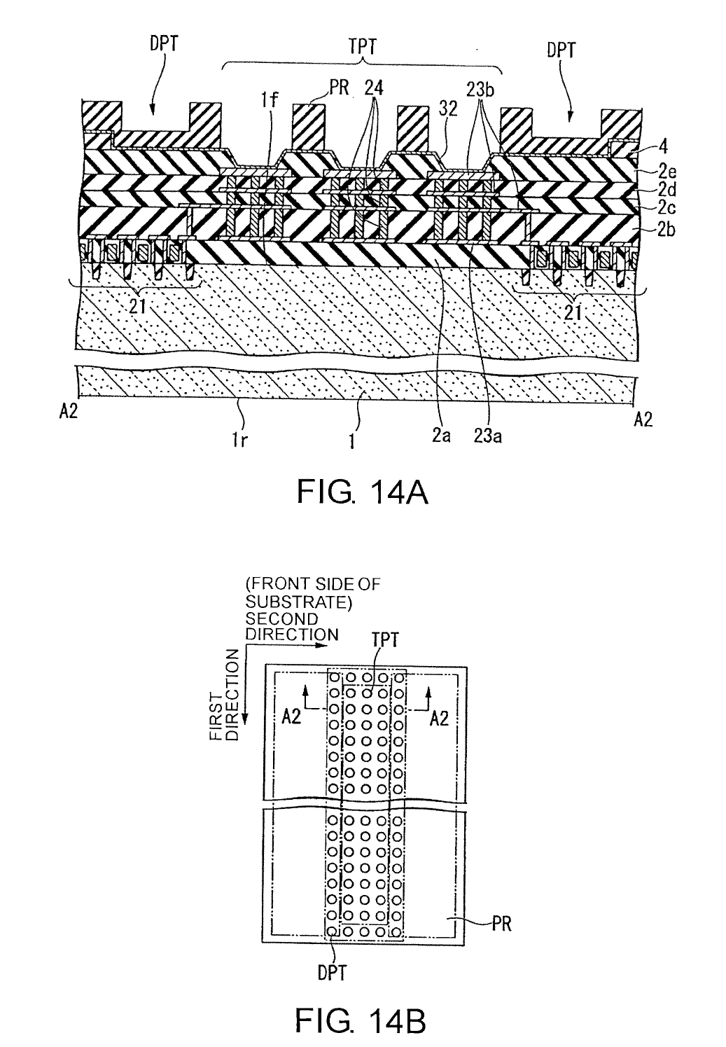

In a subsequent step illustrated in FIGS. 14A and 14B, which correspond to FIGS. 4A and 4B, dummy patterns DPT do not extend through the photoresist PR, unlike the first exemplary embodiment. In other words, the photoresist PR is left on bottoms of the openings of the dummy patterns DPT so that the seed layer 32 is not exposed. This can be achieved by controlling the opening diameter of the dummy patterns OPT. Specifically, the opening diameter of the dummy patterns DPT is reduced so that the bottoms of the dummy patterns DPT are not exposed.

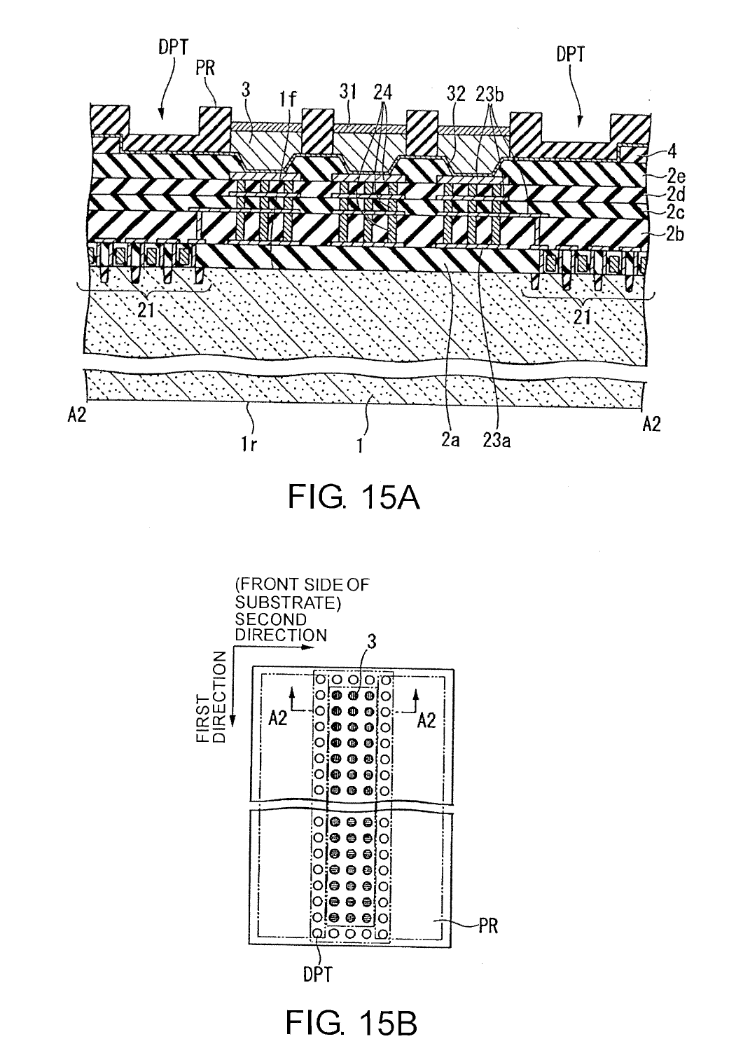

In this manner, when the photoresist PR is left on the bottoms of the openings of the dummy patterns DPT, no dummy front bump electrodes are formed in the subsequent electroplating process (see FIGS. 15A and 15B, which correspond to FIGS. 5A and 5B), unlike the first exemplary embodiment. In this case, the dummy patterns DPT that do not extend through the photoresist PR can advantageously prevent deformation of portions of the main patterns TPT. In addition to this advantageous effect, there is an additional advantageous effect that a space required for bump electrodes can be reduced in the second exemplary embodiment.

The discussion on the front side of the semiconductor substrate can be applied in the same manner to the rear side of the semiconductor substrate.

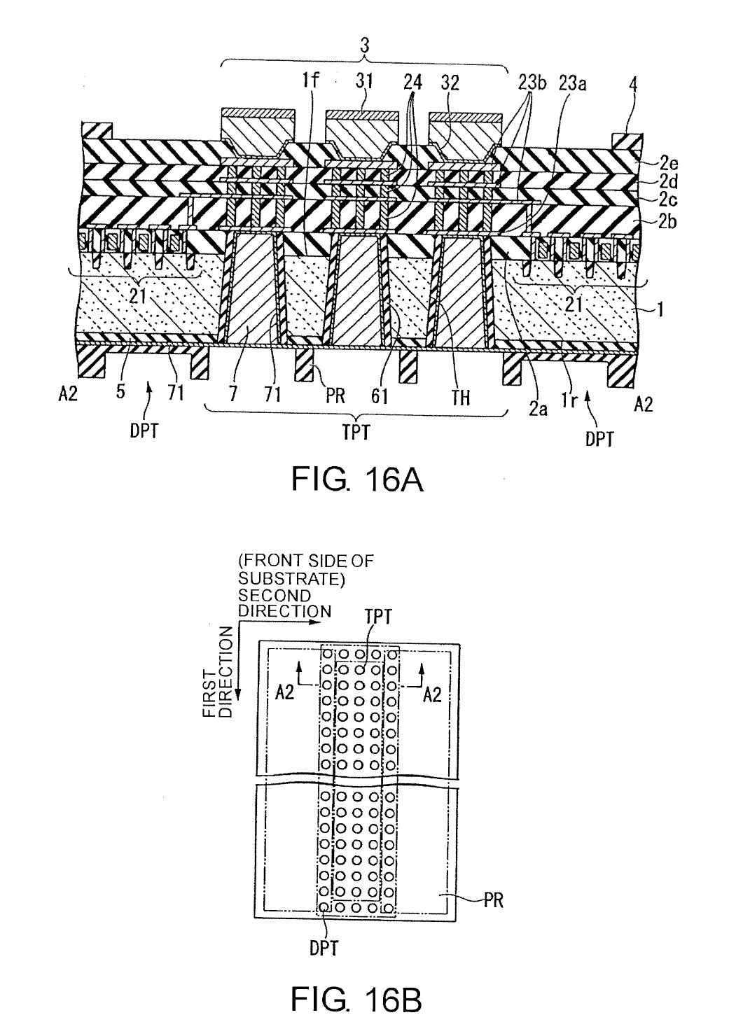

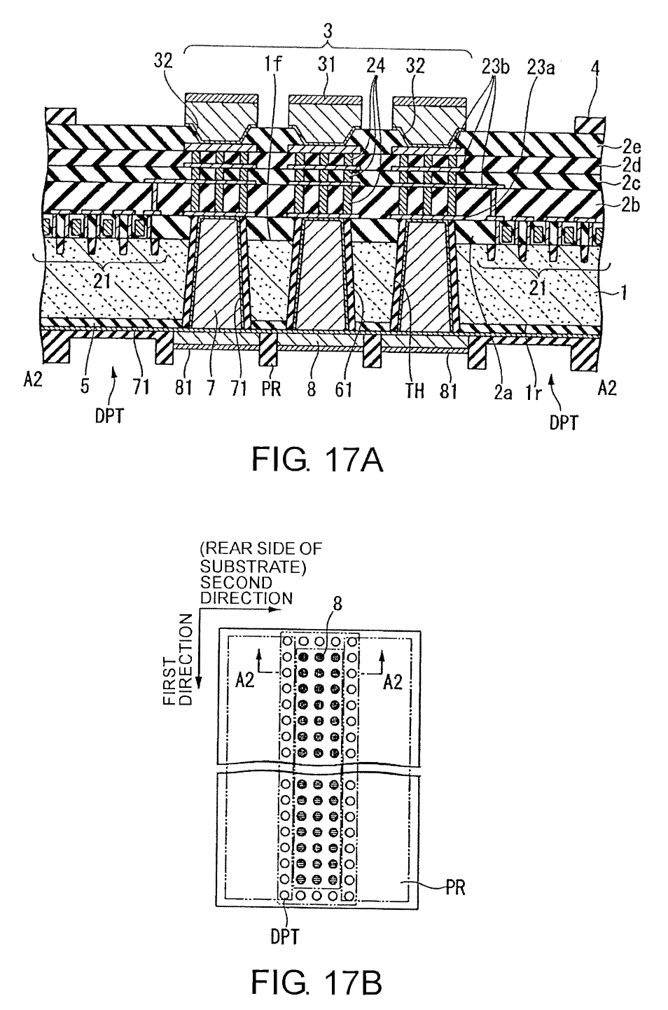

Specifically, as shown in FIGS. 16A and 16B, which correspond to FIGS. 8A and 8B, dummy patterns DPT do not extend through the photoresist PR, unlike the first embodiment. In other words, the photoresist PR is left on bottoms of the openings of the dummy patterns DPT so that the seed layer 71 is not exposed. In this manner, when the photoresist PR is left on the bottoms of the openings of the dummy patterns DPT, no dummy rear bump electrodes are formed in the subsequent electroplating process (see FIGS. 17A and 17B, which correspond to FIGS. 9A and 9B), unlike the first exemplary embodiment.

The dummy patterns DPT have the same positional relationship with the main patterns TPT as in the first embodiment. The number of bump electrodes, the number of semiconductor devices being stacked, and the like are not limited to the illustrated example, as with the first exemplary embodiment.

According to a method of manufacturing a semiconductor device according to the aforementioned second exemplary embodiment and a semiconductor device manufactured by such a method, the same advantageous effects as in the first exemplary embodiment can be obtained. In addition to those advantageous effects, there is an additional advantageous effect that a space required for bump electrodes can be reduced.

### Third Exemplary Embodiment

Next, a method of manufacturing a semiconductor device according to a third exemplary embodiment of the present invention and a semiconductor device manufactured by such a method will be described below.

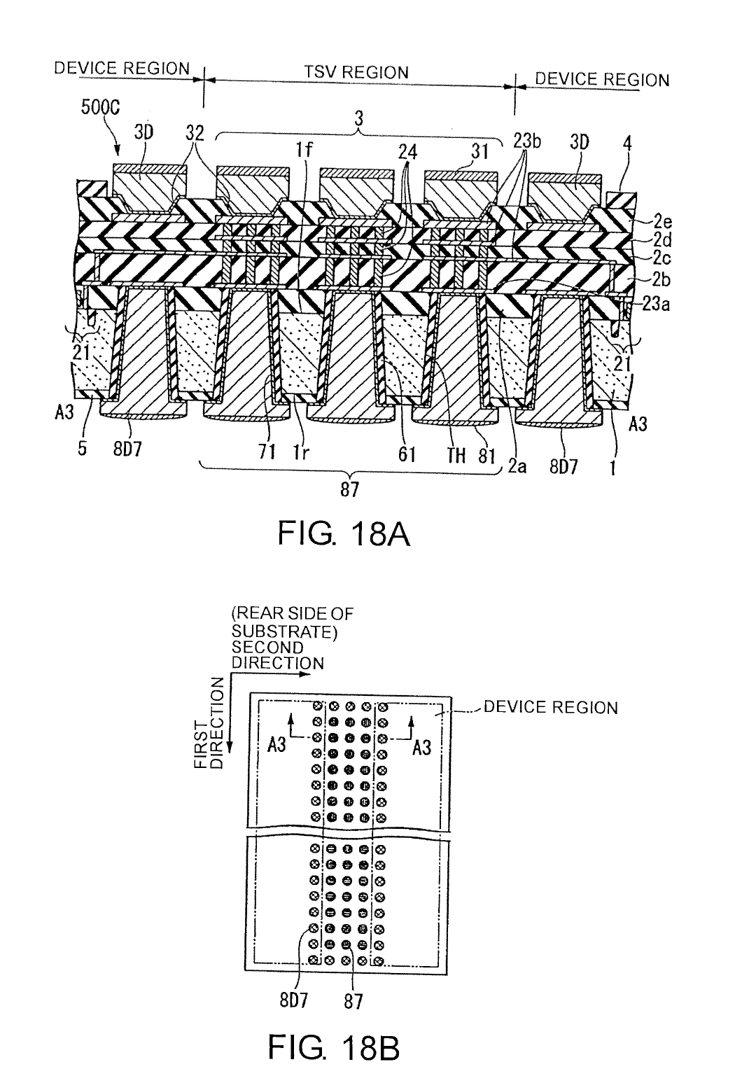

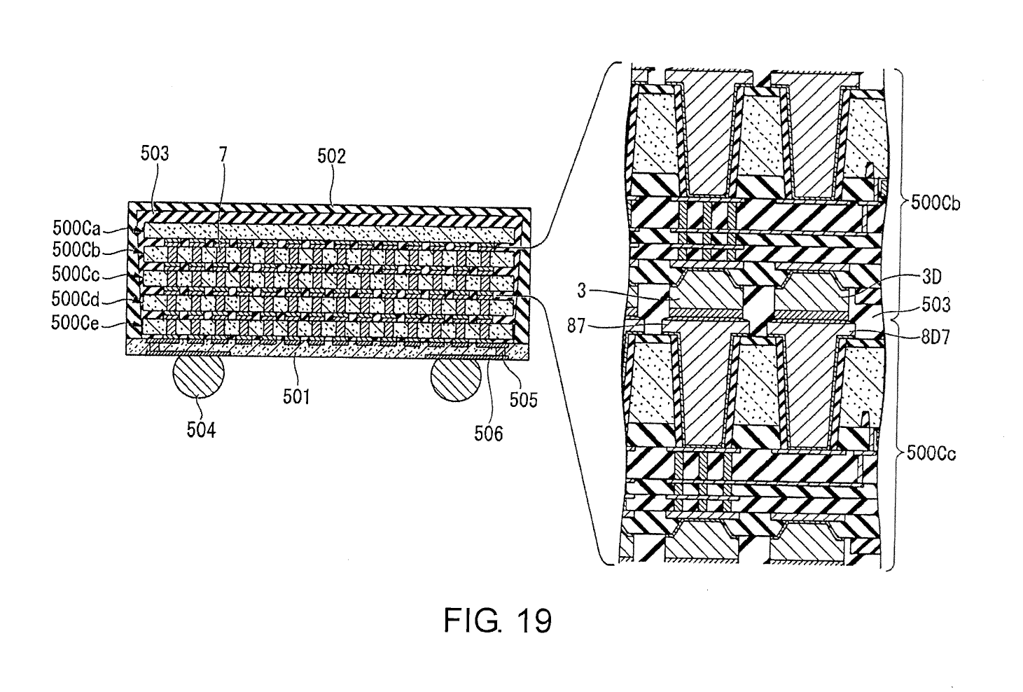

FIG. 18A is a cross-sectional view explanatory of a configuration of a semiconductor device according to a third exemplary embodiment of the present invention. FIG. 18B is a diagram showing a rear side of the semiconductor device for explaining the configuration of the semiconductor device according to the third exemplary embodiment of the present invention. FIG. 18A is a cross-sectional view taken along line A3-A3 of FIG. 18B. In other words, FIGS. 18A and 18B correspond to FIGS. 1A and 1B of the first exemplary embodiment. FIG. 19 is a diagram showing a multilayered structure in which a plurality of semiconductor devices according to the third exemplary embodiment of the present invention as illustrated in FIGS. 18A and 18B are stacked. FIG. 19 corresponds to FIG. 2 of the first embodiment. The same components as in the multilayered structure of the semiconductor device according to the first exemplary embodiment shown in FIGS. 1A, 1B, and 2 will be denoted by the same reference numerals, and the explanation thereof is omitted herein.

The semiconductor device according to the third exemplary embodiment differs from the semiconductor device according to the first exemplary embodiment in that TSV through holes TH are formed at positions corresponding to the dummy rear bump electrodes and filled with copper in the same manner as the rear bump electrodes, for forming TSV equivalents, as shown in FIGS. 18A, 18B, and 19. Thus, the dummy rear bump electrodes and the TSV equivalents can be formed concurrently with the rear bump electrodes and the TSVs in the TSV region. Therefore, as described later in connection with the manufacturing method, TSV rear bump electrodes 87 are integrally formed in the TSV region, and TSV dummy rear bump electrodes 8D7 are integrally formed in the device regions. However, no via plugs connecting the dummy front bump electrodes 3D to the TSV dummy rear bump electrodes 8D7 are formed at the portions of the dummy bump electrodes.

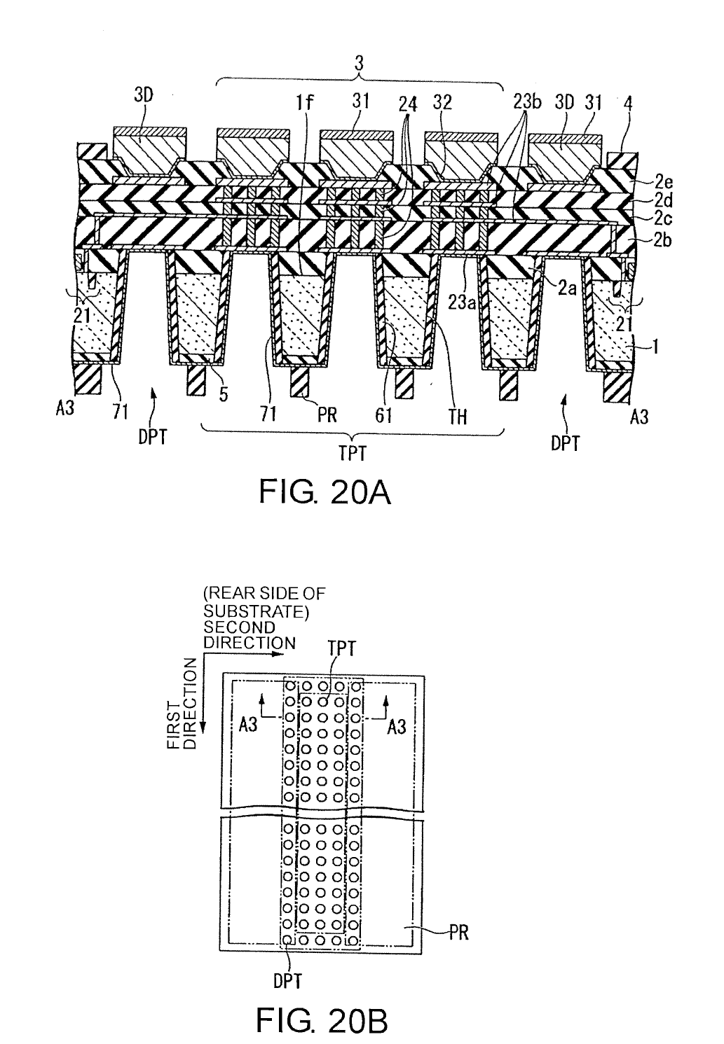

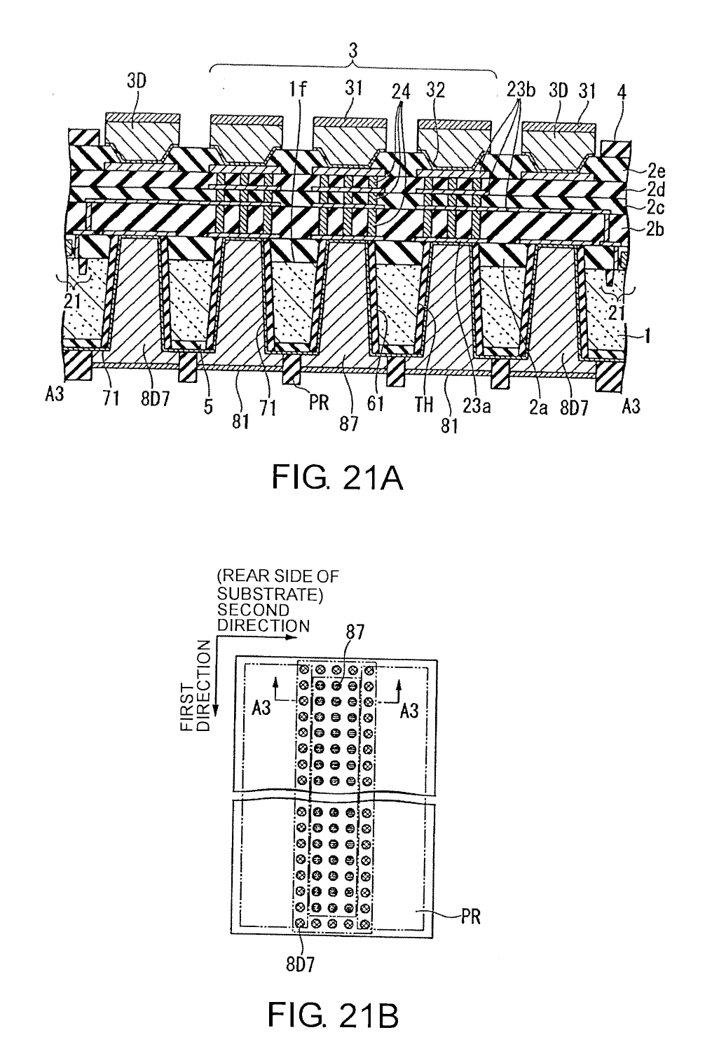

FIGS. 20A, 20B, 21A, and 21B are diagrams explanatory of a method of manufacturing a semiconductor device according to the third exemplary embodiment of the present invention as illustrated in FIGS. 18A and 18B. The description of the same steps as in the manufacturing method of the first exemplary embodiment is omitted herein for the sake of brevity.

A method of manufacturing a semiconductor device according to the third exemplary embodiment differs from that according to the first exemplary embodiment in the following points.

Specifically, in the third exemplary embodiment, as shown in FIG. 20, TSV through holes TH are formed at portions corresponding to the dummy rear bump electrodes at the same time when TSV through holes TH are formed at portions corresponding to the rear bump electrodes. Then TSV sidewall insulation rings 61 are formed, and a thin film of a seed layer 71 is formed. In that state, main patterns (first pattern group) TPT and dummy patterns (second patterns) DPT are formed in the photoresist PR.

Subsequently, as shown in FIGS. 21A and 21B, the TSV rear bump electrodes 87 in the TSV region and the TSV dummy rear bump electrodes 8D7 in the device regions are integrally formed by electroplating. Thereafter, a protective film 81 is formed as with the first exemplary embodiment.

The dummy patterns DPT have the same positional relationship with the main patterns TPT as in the first embodiment. The number of bump electrodes, the number of semiconductor devices being stacked, and the like are not limited to the illustrated example, as with the first exemplary embodiment.

According to a method of manufacturing a semiconductor device according to the aforementioned third exemplary embodiment and a semiconductor device manufactured by such a method, the same advantageous effects as in the first exemplary embodiment can be obtained. In addition to those advantageous effects, there is an additional advantageous effect that the TSV rear bump electrodes 87 and the TSV dummy rear bump electrodes 807 can integrally be formed without distinction of each other.

### Fourth Exemplary Embodiment

Next, a method of manufacturing a semiconductor device according to a fourth exemplary embodiment of the present invention and a semiconductor device manufactured by such a method will be described below.

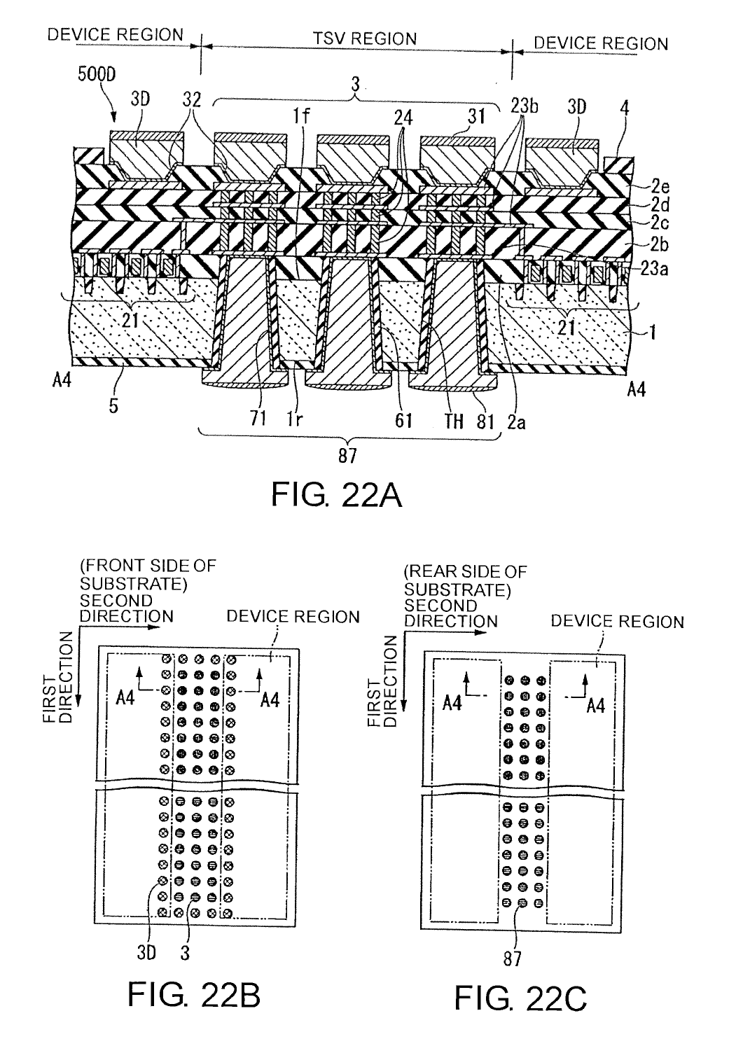

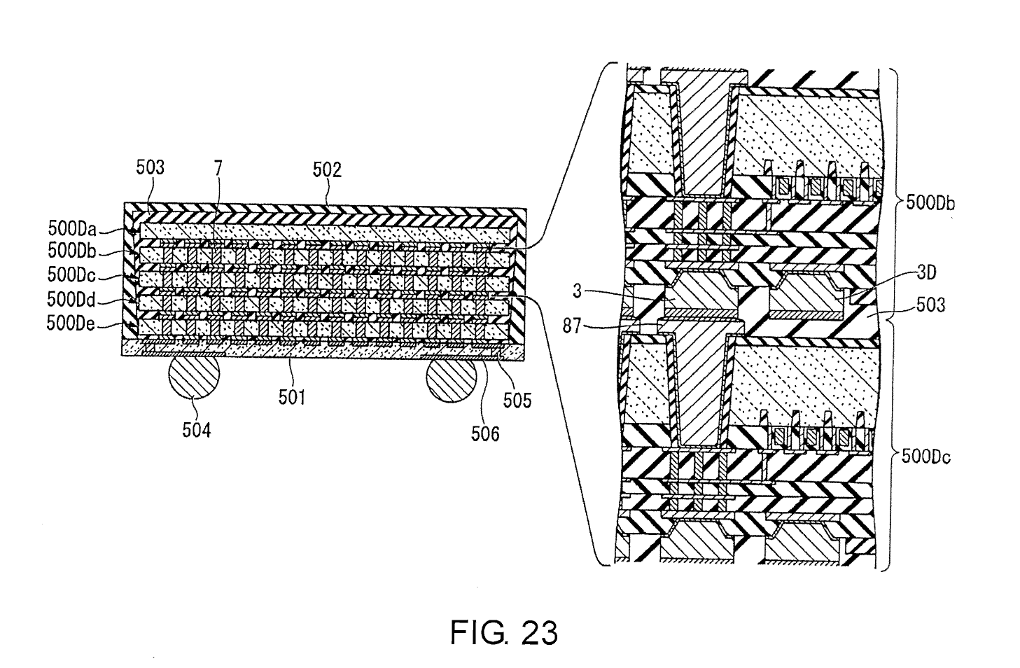

FIG. 22A is a cross-sectional view explanatory of a configuration of a semiconductor device according to a fourth exemplary embodiment of the present invention. FIG. 22B is a diagram showing a front side of the semiconductor device for explaining the configuration of the semiconductor device according to the fourth exemplary embodiment of the present invention. FIG. 22C is a diagram showing a rear side of the semiconductor device for explaining the configuration of the semiconductor device according to the fourth exemplary embodiment of the present invention. FIG. 22A is a cross-sectional view taken along line A4-A4 of FIGS. 22B and 22C. In other words, FIGS. 22A to 22C correspond to FIGS. 1A and 1B of the first exemplary embodiment. FIG. 23 is a diagram showing a multilayered structure in which a plurality of semiconductor devices according to the fourth exemplary embodiment of the present invention as illustrated in FIGS. 22A to 22C are stacked. FIG. 23 corresponds to FIG. 2 of the first exemplary embodiment. The same components as in the multilayered structure of the semiconductor device according to the first exemplary embodiment shown in FIGS. 1A, 1B, and 2 will be denoted by the same reference numerals, and the explanation thereof is omitted herein.

The semiconductor device according to the fourth exemplary embodiment differs from the semiconductor device according to the first exemplary embodiment in that it has the same structure on the front side of the substrate 1, as shown in FIGS. 22A, 22B, and 23, but no dummy rear bump electrodes on the rear side of the substrate 1 as in the second exemplary embodiment, and that TSVs and rear bump electrodes are formed integrally into TSV rear bump electrodes 87 as in the third exemplary embodiment.

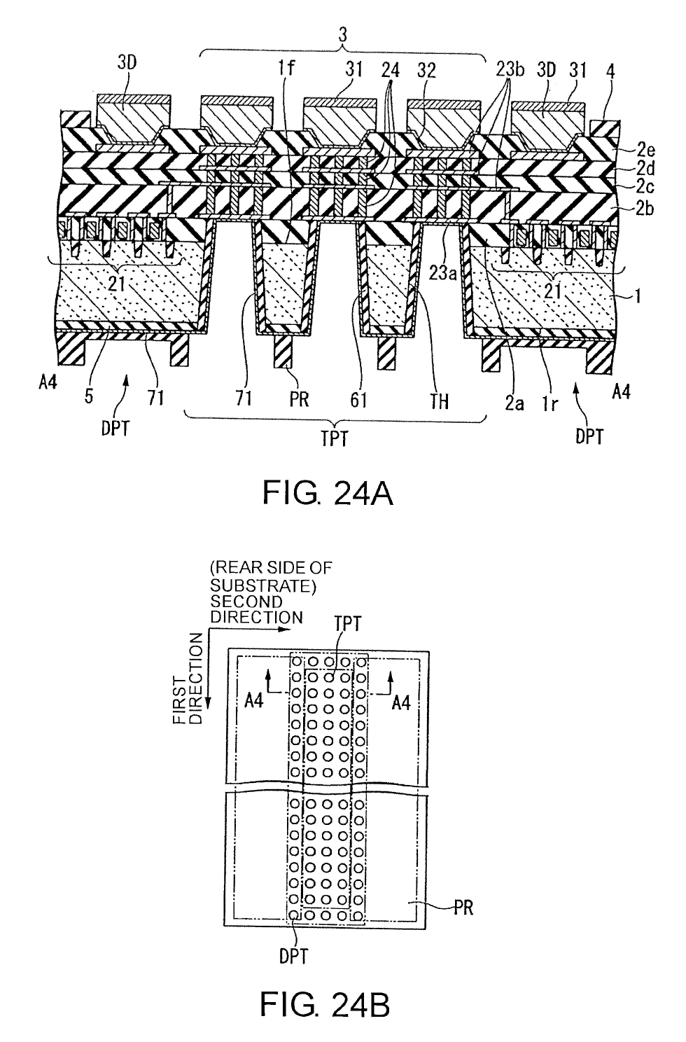

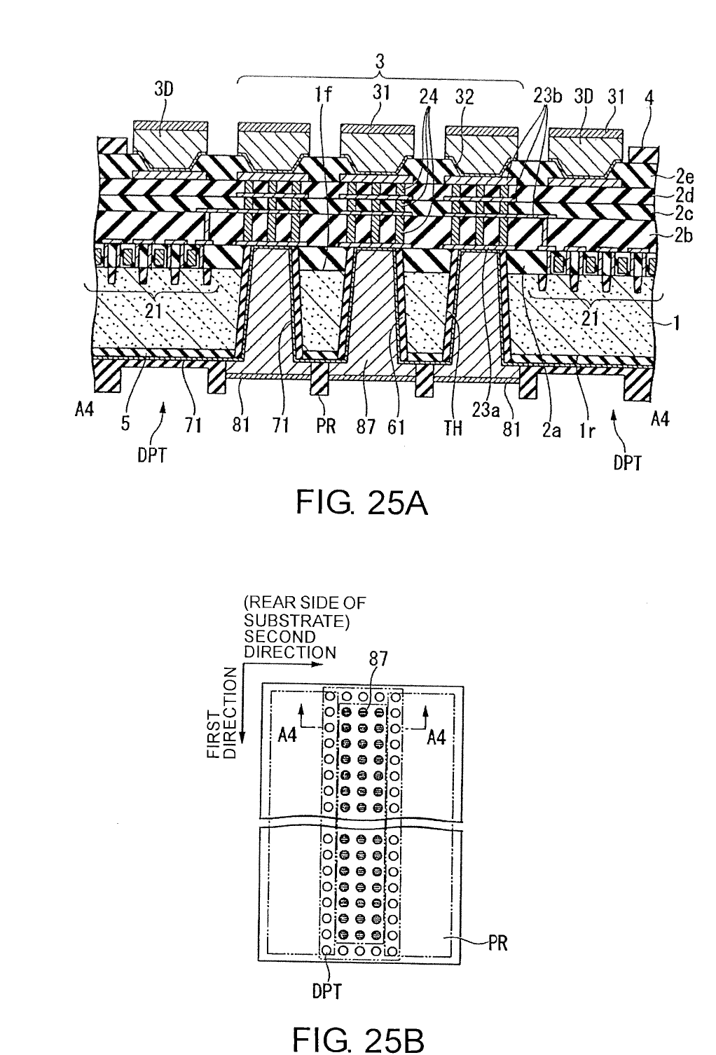

FIGS. 24A, 24B, 25A, and 25B are diagrams explanatory of a method of manufacturing a semiconductor device according to the fourth exemplary embodiment of the present invention as illustrated in FIGS. 22A and 22B. The description of the same steps as in the manufacturing method of the first exemplary embodiment is omitted herein for the sake of brevity.

A method of manufacturing a semiconductor device according to the fourth exemplary embodiment differs from that according to the first exemplary embodiment in the following points.

Specifically, in the fourth exemplary embodiment, manufacturing steps for the front side of the substrate 1 are the same as those of the first exemplary embodiment. As shown in FIGS. 24A, 24B, 25A, and 25B, however, manufacturing steps for the rear side of the substrate 1 are a combination of the manufacturing steps of the second embodiment and the manufacturing steps of the third exemplary embodiment.

Specifically, a thin film of a seed layer 71 is formed on the rear side of the substrate 1 by the identical steps to the first exemplary embodiment. As shown in FIGS. 24A and 24B, no TSVs are then formed on the rear side of the substrate 1 unlike the first exemplary embodiment. Instead, a photoresist PR having dummy patterns DPT that do not extend through the photoresist PR is formed on the rear side of the substrate 1 as in the case of the second exemplary embodiment. Then, as shown in FIGS. 25A and 25B, TSV rear bump electrodes 87 are integrally formed in the TSV region by electroplating, as in the third exemplary embodiment. At that time, the photoresist PR remains on the bottoms of the openings of the dummy patterns OPT. Accordingly, no dummy rear bump electrodes are formed at those portions, as in the second exemplary embodiment.

Subsequently, a protective film 81 is formed as in the first exemplary embodiment.

The dummy patterns DPT have the same positional relationship with the main patterns TPT as in the first exemplary embodiment. The number of bump electrodes, the number of semiconductor devices being stacked, and the like are not limited to the illustrated example, as with the first exemplary embodiment.

According to a method of manufacturing a semiconductor device according to the aforementioned fourth exemplary embodiment and a semiconductor device manufactured by such a method, the same advantageous effects as in the first exemplary embodiment can be obtained. In addition to those advantageous effects, there are additional advantageous effects that a space required for the bump electrodes can be reduced on the rear side of the substrate 1 and that the TSV rear bump electrodes 87 can integrally be formed.

<Variations Common to the First to Fourth Exemplary Embodiments>

In the above embodiments, the dummy patterns DPT include a plurality of circular dotted patterns arranged two-dimensionally. However, the shape of the dummy patterns DPT is not limited to this example. In short, the dummy patterns DPT should only be opening patterns arranged on the extension of the main patterns TPT along the first direction or on the extension of the main patterns TPT along the second direction.

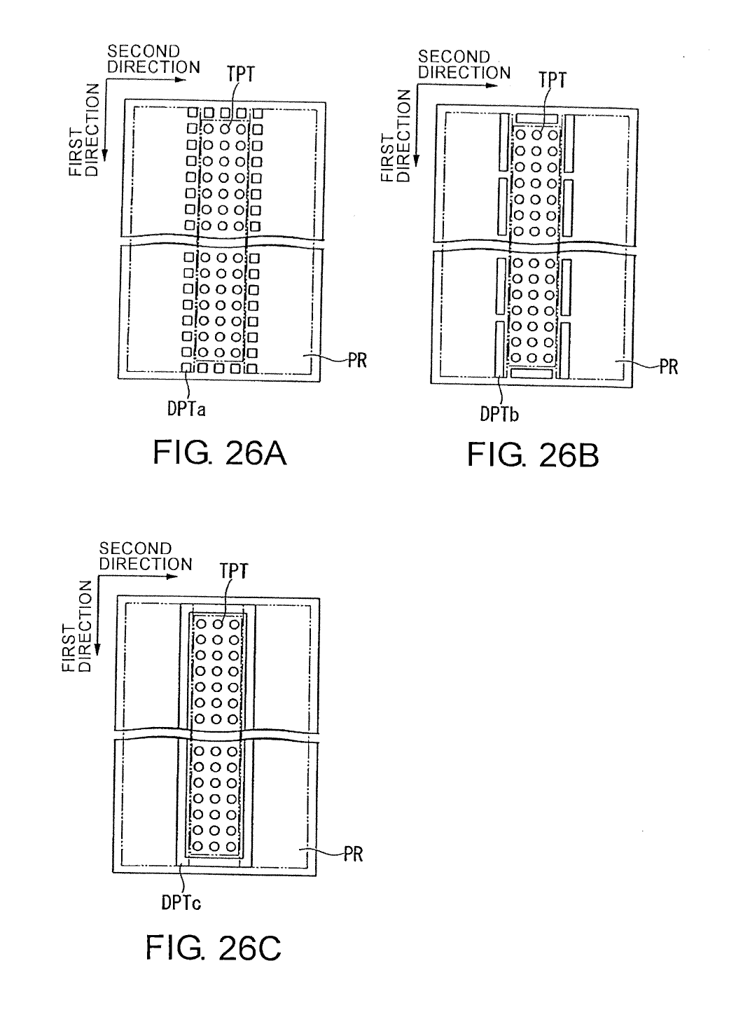

FIGS. 26A to 26C are diagrams showing examples of variations of the shape of the dummy patterns OPT.

Specifically, as shown in FIG. 26A, for example, the dummy patterns DPT may be a plurality of rectangular (particularly square) dotted patterns arranged two-dimensionally. Extensively, a plurality of dotted dummy patterns DPT may have a general polygonal shape such as a hexagonal shape.

As shown in FIG. 26B, the dummy patterns DPT may be rectangular patterns, each of which corresponds to a predetermined number of the main patterns TPT. In other words, the dummy patterns DPT may be a plurality of channel-like patterns located adjacent to the main patterns TPT.

Furthermore, as shown in FIG. 26C, the dummy patterns DPT may be a closed loop pattern continuously extending so as to surround the main patterns TPT. In other words, the dummy patterns DPT may be a ring channel-like pattern.

From the viewpoint of extension of the periodicity of patterns, the dummy patterns should preferably be dotted patterns corresponding to the individual main patterns.

Provision of multiple sets of dummy patterns, rather than a single set of dummy patterns, enhances the aforementioned advantageous effects as long as space allows. This configuration is not shown in the drawings.

<Combinations of the Above Exemplary Embodiments>

In each of the aforementioned exemplary embodiments, the dummy patterns are formed on both of the front side and the rear side of the substrate 1, irrespective of whether dummy bump electrodes are formed. Nevertheless, the dummy patterns may be formed on only one of the front side and the rear side of the substrate 1. Such a configuration is also effective.

The fourth exemplary embodiment has mentioned a combination of the first, second, and third exemplary embodiments. The present invention is not limited to such a combination. The first, second, and third exemplary embodiments may be combined in any way.

For example, one of the configurations of the first exemplary embodiment and the second exemplary embodiment is applied to one of the front side and the rear side of the substrate 1, and the other configuration is applied to the other side of the substrate 1. Alternatively, the configuration of the second exemplary embodiment is applied to the front side of the substrate 1, and the configuration of the third embodiment is applied to the rear side of the substrate 1.

<Other Conditions for Application>

The aforementioned exemplary embodiments assume forming TSVs on the rear side of the substrate after formation of circuit elements, multilayered wiring, and front bumps (via-last process). Nevertheless, the present invention is applicable to a via-first process, which includes forming TSVs before formation of circuit elements. Alternatively, the present invention is applicable to a via-middle process, which includes forming TSVs after formation of circuit elements before formation of front bumps (e.g., during a formation process of multilayered wiring). In summary, the present invention is effective irrespective of timing of formation of TSVs as long as the method of manufacturing a semiconductor device includes a step of forming bump electrodes.

The aforementioned exemplary embodiments assume a semiconductor device having TSVs. The semiconductor device may have no TSVs as long as the method of manufacturing a semiconductor device includes a step of forming bump electrodes.

According to a method of manufacturing a semiconductor device of the present invention, when a photoresist film is patterned on at least one of a front side and a rear side of a substrate, no deformation is caused to a first pattern. Therefore, no variations are caused in height of electrodes formed by an electroplating method, and no faulty connections are caused when such semiconductor devices are stacked. That is, even if deformation is caused, such deformation is generated at a second pattern.

The present invention is applicable to a semiconductor device having bump electrodes formed in opening patterns of a photoresist film, which has been patterned by a photolithography method.

Although preferred exemplary embodiments of the present invention have been described in detail, the present invention is not limited to those specific embodiments. It should be understood that various changes and modifications may be made therein without departing from the scope of the present invention defined by the appended claims.

What is claimed is:

1. A device comprising:
a semiconductor substrate including a first main surface and a second main surface opposite to the first main surface;
a plurality of first electrodes formed over the first main surface of the semiconductor substrate and arranged in line in a first direction, each of the first electrodes being configured to be supplied with a corresponding electrical potential;
a plurality of second electrodes formed over the first main surface of the semiconductor substrate and arranged in line in the first direction, each of the second electrodes being in an electrical floating state and arranged on a left side of an associated one of the first electrodes; and
a plurality of third electrodes formed over the first main surface of the semiconductor substrate and arranged in line in the first direction, each of the third electrodes being in an electrical floating state and arranged on a right side of an associated one of the first electrodes.

2. The device as claimed in claim 1, further comprising:
a plurality of fourth electrodes formed over the second main surface of the semiconductor substrate and arranged in line in the first direction, each of the fourth electrodes being vertically aligned with an associated one of the first electrodes;
a plurality of fifth electrodes formed over the second main surface of the semiconductor substrate and arranged in line in the first direction, each of the fifth electrodes being vertically aligned with an associated one of the second electrodes; and
a plurality of sixth electrodes formed over the second main surface of the semiconductor substrate and arranged in line in the first direction, each of the sixth electrodes being vertically aligned with an associated one of the third electrodes.

3. The device as claimed in claim 2, further comprising a plurality of first through-substrate vias each penetrating the semiconductor substrate, each of the first through-substrate vias being vertically aligned with an associated one the first electrodes and with an associated one of the fourth electrodes.

4. The device as claimed in claim 3, further comprising:
a plurality of second through-substrate vias each penetrating the semiconductor substrate, each of the second through-substrate vias being vertically aligned with an associated one the second electrodes and with an associated one of the fifth electrodes; and
a plurality of third through-substrate vias each penetrating the semiconductor substrate, each of the third through-substrate vias being vertically aligned with an associated one the third electrodes and with an associated one of the sixth electrodes.

5. The device as claimed in claim 1, further comprising:
a plurality of fourth electrodes formed over the second main surface of the semiconductor substrate and arranged in line in the first direction, each of the fourth electrodes being vertically aligned with an associated one of the first electrodes; and
a plurality of first through-substrate vias each penetrating the semiconductor substrate, each of the first through-substrate vias being vertically aligned with an associated one the first electrodes and with an associated one of the fourth electrodes.

6. The device as claimed in claim 1,
wherein the device further comprises a plurality of first transistors each formed in a first portion of the semiconductor substrate on a side of the first main surface, and a plurality of second transistors each formed in a second portion of the semiconductor substrate on a side of the first main surface; and
wherein at least one of the second electrodes is formed over the first portion of the semiconductor substrate and at least one of the third electrodes is formed over the second portion of the semiconductor substrate.

7. The device as claimed in claim 1, further comprising a plurality of fourth electrodes formed over the first main surface of the semiconductor substrate and arranged in line in a first direction, each of the first electrodes being configured to be supplied with a corresponding electrical potential and being between an associated one of the first electrodes and an associated one of the second electrodes.

8. A device comprising:
a semiconductor substrate including a first main surface and a second main surface opposite to the first main surface;
a plurality of first through-substrate vias each penetrating the semiconductor substrate, the first through-substrate vias being arranged to form a matrix including a plurality of rows and columns;
a plurality of first electrodes formed over the first main surface of the semiconductor substrate, each the first electrodes being vertically aligned with an associated one of the first through-substrate vias and electrically connected to a selected one of the first through-substrate vias;
a first set of dummy electrodes each being in an electrical floating state; and
a second set of dummy electrodes each being in an electrical floating state;
each of the first and second sets of dummy electrodes being formed over one of the first and second main surfaces of the semiconductor substrate to sandwich the first electrodes therebetween.

9. The device as claimed in claim 8, further comprising:
a plurality of second electrodes formed over the second main surface of the semiconductor substrate, each the second electrodes being vertically aligned with and electrically connected to an associated one of the first through-substrate vias;
a third set of dummy electrodes each being in an electrical floating state; and
a fourth set of dummy electrodes each being in an electrical floating state;
each of the third and fourth sets of dummy electrodes being formed over the other of the first and second main surfaces of the semiconductor substrate to sandwich the second electrodes therebetween.

10. The device as claimed in claim 9, further comprising a plurality of second through-substrate vias each penetrating the semiconductor substrate and a plurality of third through-substrate vias each penetrating the semiconductor substrate, each of the second through-substrate vias being between an associated one of the first set of dummy electrodes and an associated one of the third set of dummy electrodes, and each of the third through-substrate vias being between an associated one of the second set of dummy electrodes and an associated one of the fourth set of dummy electrodes.

11. A device comprising:
a semiconductor substrate including first, second and third areas, the second area being between the first and third areas;
a plurality of first through-substrate vias each formed in the second area and each penetrating the semiconductor substrate, the first through-substrate vias being arranged in line in a first direction;
a plurality of first electrodes each formed over the second area of the semiconductor substrate, the first electrodes being arranged in line in the first direction so that each of the first electrodes being vertically aligned with an associated one of the first through-substrate vias;
a plurality of second electrodes each formed over the first area of the semiconductor substrate and in an electrical floating state, the second electrodes being arranged in line in the first direction; and
a plurality of third electrodes each formed over the third area of the semiconductor substrate and in an electrical floating state, the third electrodes being arranged in line in the first direction so that each of the third electrodes cooperates with an associated one of the second electrodes to sandwich an associated one of the first electrodes therebetween in a second direction that is substantially perpendicular to the first direction.

12. The device as claimed in claim 11,
wherein the semiconductor substrate including a first main surface and a second main surface opposite to the first main surface;
wherein each of the first, second and third electrodes is formed on a side of the main surface of the semiconductor substrate;
wherein the device further comprises a plurality of fourth electrodes each formed on a side of the second main surface of the semiconductor substrate, the fourth electrodes being arranged in line in the first direction so that each of the fourth electrodes is vertically aligned with an associated one of the first through-substrate vias.

13. The device as claimed in claim 12, further comprising a plurality of fifth electrodes and a plurality of sixth electrodes each formed on a side of the second main surface of the semiconductor substrate, the fifth electrodes being arranged in line in the first direction so that each of the fifth electrodes is vertically aligned with an associated one of the second electrodes, and the sixth electrodes being arranged in line in the first direction so that each of the sixth electrodes being vertically aligned with an associated one of the third electrodes.

14. The device as claimed in claim 13, further comprising:
a plurality of second through-substrate vias each formed in the first area and each penetrating the semiconductor substrate, the second through-substrate vias being arranged in line in the first direction so that each of the second through-substrate vias is vertically aligned with associated ones of the second and fifth electrodes; and
a plurality of third through-substrate vias each formed in the third area and each penetrating the semiconductor substrate, the third through-substrate vias being arranged in line in the first direction so that each of the third through-substrate vias is vertically aligned with associated ones of the third and sixth electrodes

15. The device as claimed in claim 11, further comprising a multi-level wiring structure inserted between the semiconductor substrate and each of the first, second and third electrodes.

16. The device as claimed in claim 15, wherein the multi-level wiring structure comprises a plurality of wiring layers formed at different levels and a plurality of vias each connecting selected ones of the wiring layer that are at different levels to each other.

17. The device as claimed in claim 16, wherein each of the first through-substrate vias is connected to a lowermost wiring layer of the multi-level wiring structure.

18. The device as claimed in claim 17, wherein each of the first electrodes is connected to an uppermost wiring layer of the multi-level wiring structure.
